(19) United States
(12) Patent Application Publication
(10) Pub. No.: US 2026/0127545 A1
(43) Pub. Date: May 7, 2026

(54) SIMULATION MODEL GENERATION METHOD, SIMULATION MODEL GENERATION PROGRAM, AND SIMULATION MODEL GENERATION SYSTEM

(71) Applicant: PANASONIC INTELLECTUAL PROPERTY MANAGEMENT CO., LTD., Osaka (JP)

(72) Inventors: Kazuya NAKAZAWA, Osaka (JP); Hirokazu SO, Kyoto (JP); Ryo MATSUBARA, Osaka (JP)

(73) Assignee: PANASONIC INTELLECTUAL PROPERTY MANAGEMENT CO., LTD., Osaka (JP)

(21) Appl. No.: 19/485,017

(22) PCT Filed: May 16, 2024
(86) PCT No.: PCT/JP2024/018122

§ 371 Date: Nov. 17, 2025

(30) Foreign Application Priority Data
May 17, 2023 (JP) 2023-081894

(51) Int. Cl. G06Q 10/087; G06F 30/27

(52) U.S. Cl. CPC G06Q 10/087; G06F 30/27

(57) ABSTRACT

Provided is a simulation model generation method that is executed by a calculation device connected, so as to enable data communication, to a management system for managing the inventory state of articles. The simulation model generation method includes acquiring, from the management system, slot information including the locations of slots for storing the articles, and generating a simulation model on the basis of the slot information.

### TECHNICAL FIELD

The present disclosure relates to a simulation model generation method, a simulation model generation program, and a simulation model generation system.

### BACKGROUND ART

In the related art, a large number of articles are managed in a warehouse such as an article delivery base, and work such as picking of the articles is performed in response to a request. Patent Literature 1 discloses a configuration in which a pallet transport allocation is optimized by executing a simulation in order to improve the capability of a transport carriage system in an automatic warehouse in which loads are loaded and unloaded.

### CITATION LIST

### Patent Literature

Patent Literature 1: JP 2020-111455A

### SUMMARY OF INVENTION

### Technical Problem

In order to optimize the warehouse work such as picking, a simulation model for managing the warehouse work is considered to be effective. However, in order to generate the simulation model for managing the warehouse work, it is necessary to investigate the layout of the warehouse and the quantity and type of shelves, articles, or the like in the warehouse according to a simulation target warehouse. However, the quantity and type of shelves, articles, or the like in the warehouse may be enormous, and it may take time and effort to manually investigate them.

Patent Literature 1 does not consider the quantity and type of shelves, articles, or the like in the simulation target warehouse. Further, the simulation model corresponding to each simulation target warehouse was not generated.

The present disclosure has been made in view of the above-described circumstances of the related art, and an object thereof is to automatically generate a simulation model for managing warehouse work according to a simulation target warehouse, and to achieve convenience of the warehouse work.

### Solution to Problem

The present disclosure provides a simulation model generation method executed by an arithmetic device, the arithmetic device being connected to a management system that manages a stock state of articles so as to be able to perform data communication, and the method includes: acquiring, from the management system, slot information including a position of a slot in which the articles are stored; and generating a simulation model based on the slot information.

Further, the present disclosure provides a program for causing an arithmetic device, the arithmetic device being connected to a management system that manages stock information of articles so as to be able to perform data communication, to execute processing of: acquiring, from the management system, slot information including a position of a slot in which the articles are stored; and generating a simulation model based on the slot information.

Further, the present disclosure provides a simulation model generation system including an arithmetic device, the arithmetic device being connected to a management system that manages a stock state of articles so as to be able to perform data communication, and the simulation model generation system includes: by the arithmetic device, acquiring slot information including a position of a slot in which the articles are stored from the management system; and generating a simulation model based on the slot information.

### Advantageous Effects of Invention

According to the present disclosure, it is possible to automatically generate a simulation model for managing warehouse work according to a simulation target warehouse, and to achieve convenience of the warehouse work.

### BRIEF DESCRIPTION OF DRAWINGS

FIG. 1 is a block diagram illustrating a configuration example of a simulation model generation system according to Embodiment 1;

FIG. 2 is a block diagram illustrating a configuration example of an arithmetic device according to Embodiment 1;

FIG. 3 is a sequence diagram of processing of the simulation model generation system according to Embodiment 1;

FIG. 4 is a table diagram illustrating data before and after conversion processing by the arithmetic device according to Embodiment 1;

FIG. 5 is a schematic diagram illustrating a simulation model according to Embodiment 1;

FIG. 6 is a flowchart of processing of a warehouse management system according to Embodiment 1;

FIG. 7 is a flowchart of data conversion processing according to Embodiment 1;

FIG. 8 is a flowchart of slot information conversion processing according to Embodiment 1;

FIG. 9 is a flowchart of passage information generation processing according to Embodiment 1;

FIG. 10 is a schematic diagram for illustrating the passage information generation processing according to Embodiment 1;

FIG. 11 is a flowchart of region information generation processing according to Embodiment 1;

FIG. 12 is a schematic diagram for illustrating the region information generation processing according to Embodiment 1;

FIG. 13 is a flowchart of wall information generation processing according to Embodiment 1;

FIG. 14 is a schematic diagram for illustrating the wall information generation processing according to Embodiment 1;

FIG. 15 is a flowchart of pick list generation processing according to Embodiment 1;

FIG. 16 is a flowchart of stock information generation processing according to Embodiment 1;

FIG. 17 is a flowchart of simulation model generation and simulation execution processing according to Embodiment 1;

FIG. 18 is a schematic diagram illustrating an example of a simulation result according to Embodiment 1;

FIG. 19 is a schematic diagram illustrating an example of the simulation result according to Embodiment 1;

FIG. 20 is a flowchart of slot information conversion processing according to a modification of Embodiment 1;

FIG. 21 is a schematic diagram for illustrating unification of reference points of a pick zone according to the modification of Embodiment 1;

FIG. 22 is a flowchart of 3D model generation processing according to the modification of Embodiment 1;

FIG. 23 is a block diagram illustrating a configuration example of a simulation model generation system according to Embodiment 2;

FIG. 24 is a block diagram illustrating a configuration example of an arithmetic device according to Embodiment 2;

FIG. 25 is a sequence diagram of processing of the simulation model generation system according to Embodiment 2;

FIG. 26 is a table diagram illustrating data before and after conversion processing by the arithmetic device according to Embodiment 2;

FIG. 27 is a schematic diagram illustrating a simulation model according to Embodiment 2;

FIG. 28 is a flowchart of processing of a transport management system according to Embodiment 2;

FIG. 29 is a flowchart of data conversion processing according to Embodiment 2;

FIG. 30 is a flowchart of slot information conversion processing according to Embodiment 2;

FIG. 31 is a flowchart of path information generation processing according to Embodiment 2;

FIG. 32 is a flowchart of pick list generation processing according to Embodiment 2.

FIG. 33 is a flowchart of stock information generation processing according to Embodiment 2;

FIG. 34 is a flowchart of simulation model generation and simulation execution processing according to Embodiment 2;

FIG. 35 is a schematic diagram illustrating an example of a simulation result according to Embodiment 2; and

FIG. 36 is a schematic diagram illustrating an example of the simulation result according to Embodiment 2.

### DESCRIPTION OF EMBODIMENTS

Hereinafter, various embodiments specifically disclosing a simulation model generation method, a simulation model generation program, and a simulation model generation system according to the present disclosure will be described in detail with reference to the drawings as appropriate. However, unnecessarily detailed description may be omitted. For example, detailed description of already well-known matters and redundant description of substantially the same configuration may be omitted. This is to avoid unnecessary redundancy of the following description and to facilitate understanding of those skilled in the art. The accompanying drawings and the following description are provided for those skilled in the art to fully understand the present disclosure, and are not intended to limit subject matters described in the claims.

### Embodiment 1

### System Configuration

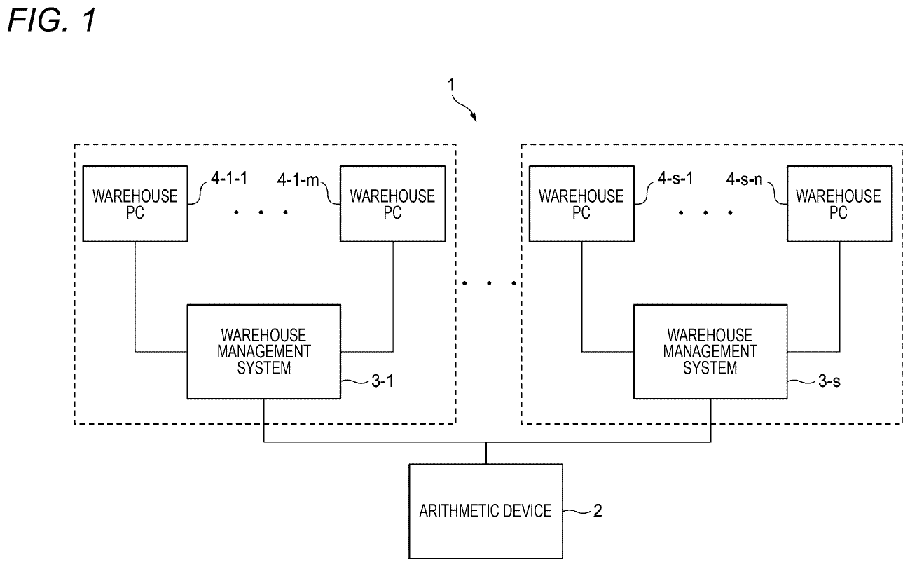

FIG. 1 is a block diagram illustrating a configuration example of a simulation model generation system 1 according to Embodiment 1. The simulation model generation system 1 includes an arithmetic device 2 and at least one warehouse management system 3-1, . . . , or 3-s (s being an integer of 2 or more). The simulation model generation system 1 is a system in which the arithmetic device 2 automatically generates a simulation model for managing warehouse work based on information on warehouses stored in the warehouse management systems 3-1 to 3-s, thereby supporting study of optimization of the work.

The arithmetic device 2 is implemented using a general-purpose computer device (for example, a personal computer or a server computer). The arithmetic device 2 is connected to one or a plurality of warehouse management systems 3 so as to allow input and output of data therebetween. The arithmetic device 2 may be connectable to a user terminal (not illustrated) (for example, a personal computer (hereinafter, referred to as a “PC”).

The warehouse management system 3-1 is a system for managing a stock status of articles managed in a warehouse, loading and unloading of the articles in the warehouse, and the like. The warehouse management system 3-1 may be referred to as a warehouse management system (WMS). The warehouse management system 3-1 may be capable of managing one or a plurality of warehouses, and may be connectable to warehouse PCs 4-1-1, . . . , 4-1-m (m being an integer of 2 or more) for management of the warehouses. The other warehouse management systems are similar to the warehouse management system 3-1. For example, the warehouse management system 3-s may be connectable to warehouse PCs 4-s-1, . . . , 4-s-n (n being an integer of 2 or more).

The warehouse PC 4-1-1 is installed in, for example, the warehouse (not illustrated), and records the stock status of the articles managed in the warehouse, and the like. The warehouse PC 4-1-1 may record the stock status and the like in real time by receiving various types of data from a terminal such as a handy terminal. The warehouse PC 4-1-1 is connectable to the warehouse management system 3-1, and can transmit the stock status of the articles managed in the warehouse, and the like, to the warehouse management system 3-1. The other warehouse PCs are similar to the warehouse PC 4-1-1. For example, the warehouse PC 4-s-1 may be connectable to the warehouse management system 3-s. The warehouse PCs 4-1-1 to 4-1-m and the warehouse PCs 4-s to 1-4-n may be installed in different warehouses. In the following description, the warehouse management system 3-1 and the warehouse PC 4-1-1 are used when the warehouse management system and the warehouse PC need to be described individually, and reference numerals are omitted when they are collectively described.

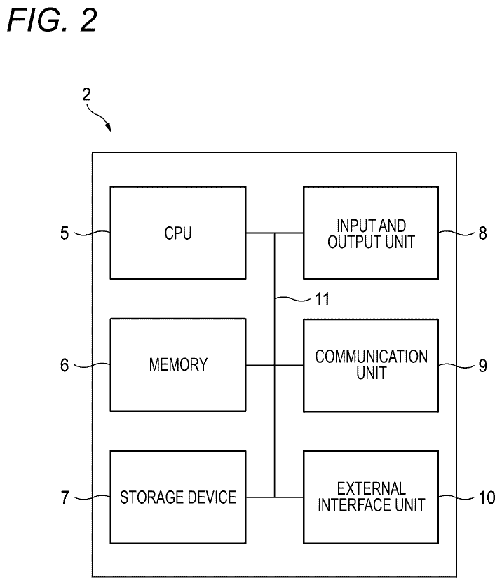

FIG. 2 is a block diagram illustrating a hardware configuration of the arithmetic device 2 according to Embodiment 1. The arithmetic device 2 is composed of a central processing unit (hereinafter, referred to as a “CPU”) 5, a memory 6, a storage device 7, an input and output unit 8, a communication unit 9, and an external interface unit 10. The individual parts provided in the arithmetic device 2 are communicably connected by an internal bus 11.

The CPU 5 implements various functions by reading and executing various types of data and programs held in the memory 6 or the storage device 7. The CPU 5 may be another arithmetic circuit such as a micro processing unit (hereinafter, referred to as an “MPU”), a digital signal processor (hereinafter, referred to as a “DSP”), a graphical processing unit (hereinafter, referred to as a “GPU”), or a field programmable gate array (hereinafter, referred to as an “FPGA”), or may be used in combination with other arithmetic circuits.

The memory 6 includes, for example, a volatile/nonvolatile storage device such as a random access memory (hereinafter, referred to as a “RAM”) and a read only memory (hereinafter, referred to as a “ROM”), and temporarily stores a program and data necessary for executing the operation of the arithmetic device 2, as well as data or information generated during the operation. The RAM is, for example, a work memory used when the arithmetic device 2 operates. The ROM stores and holds, for example, a program and data for controlling the arithmetic device 2 in advance.

The storage device 7 is a storage region for storing and holding various types of data and programs, and includes, for example, a hard disk drive (hereinafter, referred to as an “HDD”) or a solid state drive (hereinafter, referred to as an “SSD”).

The input and output unit 8 receives an instruction from a user via, for example, a keyboard and a mouse (not illustrated). The input and output unit 8 outputs various types of information by, for example, a display (not illustrated).

The communication unit 9 communicates with an external device such as a warehouse management system or the user terminal (not illustrated) via a network (not illustrated), and transmits and receives various types of data or signals. The communication unit 9 may support either wired communication or wireless communication. A communication method used by the communication unit 9 may be, for example, a wide area network (hereinafter, referred to as “WAN”), a local area network (hereinafter, referred to as a “LAN”), a long term evolution (hereinafter, referred to as an “LTE”), mobile communications such as 5G, power line communications, short-distance wireless communications such as Wi-Fi (registered trademark) and Bluetooth (registered trademark), or a combination of these.

The external interface unit 10 is an interface for transmitting and receiving data to and from the external device. The warehouse management system may also be implemented by a hardware configuration similar to that of the arithmetic device 2.

### Processing Sequence

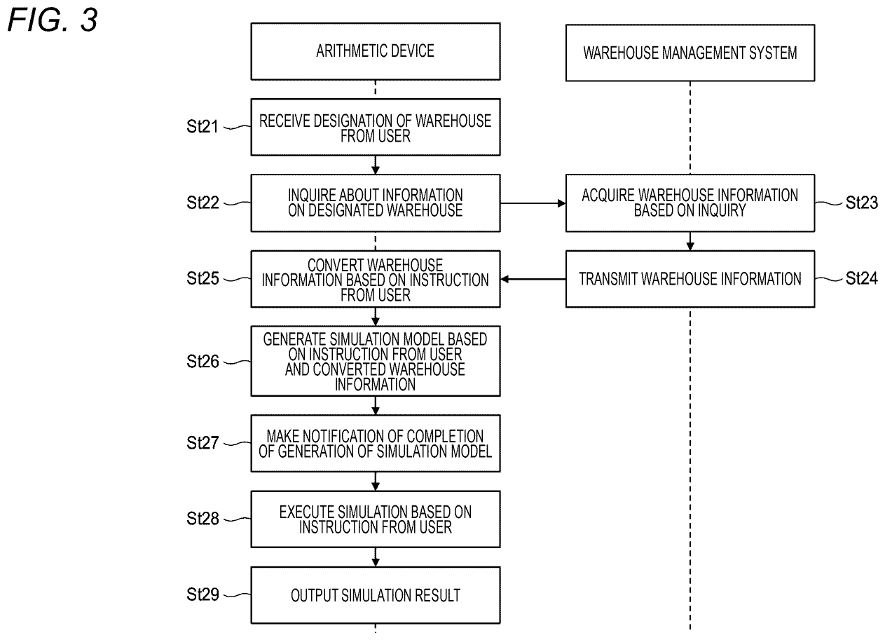

A processing sequence of the simulation model generation system 1 according to Embodiment 1 will be described with reference to FIG. 3. Processing in each processing sequence is performed in cooperation with the arithmetic device 2 and the warehouse management system. However, some processing of the sequence may be executed based on a user operation.

The arithmetic device 2 receives an input designating a warehouse as a simulation target by the user (step St21). The input content may be, for example, an identification number such as a name, a location, or an ID of the simulation target warehouse. The input may be performed directly on the arithmetic device 2 or may be performed from a user terminal (not illustrated) or the like. Here, description will be given assuming that the warehouse PC 4-1-1 is installed in the simulation target warehouse and the simulation target warehouse is managed by the warehouse management system 3-1.

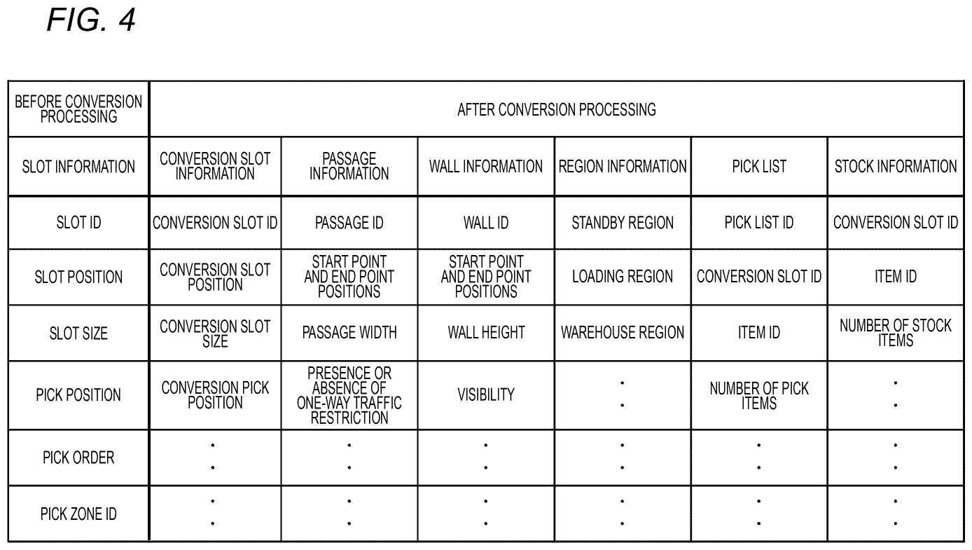

The arithmetic device 2 inquires of the warehouse management system 3-1 about the simulation target warehouse based on the input in step St21 (step St22). The content of the inquiry is to request information necessary for automatic generation of the simulation model. The information will be described later with reference to FIG. 4.

In response to the inquiry from the arithmetic device 2, the warehouse management system 3-1 acquires information on the simulation target warehouse stored in the warehouse management system 3-1 (step St23). A method through which the warehouse management system 3-1 acquires the information is not particularly limited. For example, when the warehouse management system 3-1 acquires the information, the warehouse management system 3-1 may retrieve the information by searching a storage device or the like of the warehouse management system 3-1. Further, when necessary information is not found, the warehouse management system 3-1 may acquire the information by making an inquiry to the warehouse PC 4-1-1 of the simulation target warehouse. Hereinafter, the information on the warehouse acquired by the warehouse management system 3-1 may be referred to as “warehouse information”.

The warehouse management system 3-1 transmits the warehouse information acquired in step St23 to the arithmetic device 2 (step St24).

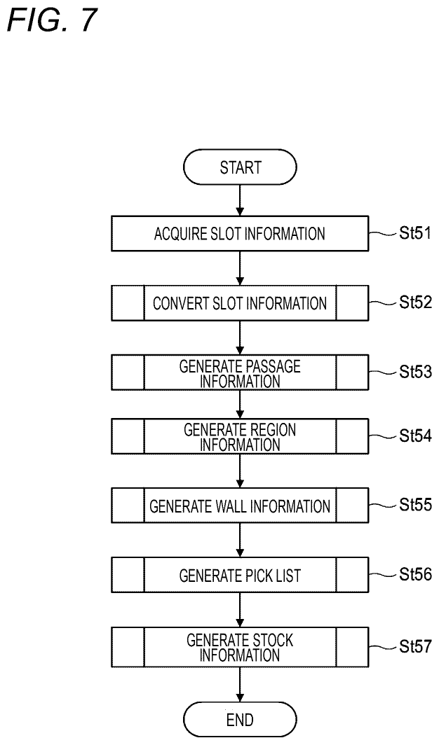

When there is the instruction from the user, the arithmetic device 2 executes data conversion processing on the warehouse information acquired in step St24 (step St25). The instruction of the user may be directly input to the arithmetic device or may be performed from a user terminal (not illustrated) or the like. This similarly applies to the processing of the following steps St26 and St28. Hereinafter, the converted information obtained by the data conversion processing may be referred to as “converted warehouse information”. The converted warehouse information will be described later with reference to FIG. 4. Details of the data conversion processing will be described later with reference to FIGS. 7 to 16.

When there is the instruction from the user, the arithmetic device 2 automatically generates the simulation model for virtually managing the warehouse work in the simulation target warehouse based on the converted warehouse information obtained by the conversion processing in step St25 (step St26). The simulation model is generated in, for example, a cyber space.

When the generation of the simulation model is completed, the arithmetic device 2 notifies the user of the completion (step St27). The arithmetic device 2 may notify the user by the input and output unit 8 such as the display (not illustrated).

When there is the instruction from the user, the arithmetic device 2 executes a simulation based on the generated simulation model (step St28).

When the executed simulation ends, the arithmetic device 2 outputs a simulation result (step St29). The arithmetic device 2 may display the simulation result on, for example, the display (not illustrated). The arithmetic device 2 may output the simulation result as, for example, a text file.

### Warehouse Information

FIG. 4 is a table diagram illustrating warehouse information before the data conversion processing by the arithmetic device 2 and the converted warehouse information after the data conversion processing. The warehouse information acquired by the warehouse management system 3-1 in the processing of step St23 of FIG. 3 is slot information of each slot constituting all slots of the simulation target warehouse. In the present embodiment, the slot refers to a minimum unit of an article storage space partitioned by a partition plate, a shelf plate, or the like in a shelf installed in the warehouse. Therefore, one shelf may include a plurality of slots. Each slot in the warehouse is provided with slot information corresponding to the slot, regardless of whether articles are stored therein.

The slot information includes a slot ID, a slot position, a slot size, a pick position, a pick order, and a pick zone ID as data. The slot ID is an identifier of a slot, and a different slot ID is assigned to each slot. The slot position indicates a three-dimensional position of the slot in the warehouse, and is represented using, for example, three-dimensional coordinates. The slot size indicates the size of the slot, and is represented using, for example, a distance between two points in a three-dimensional coordinate space. The pick position indicates a three-dimensional position when the worker picks the article stored in the slot, and is represented using, for example, three-dimensional coordinates. The pick order indicates the sequence in which the worker picks the articles stored in the slot, and is represented by, for example, numbers. The worker performs a work (for example, picking of the articles disposed in the slot) for the slot to which the same pick zone ID is assigned.

In the present embodiment, description will be given assuming that the slot information includes the slot ID, the slot position, the slot size, the pick position, the pick order, and the pick zone ID. However, the data configuration, the data name, and the like of the slot information may be different for each warehouse management system. For example, even if the same type of information is stored in the warehouse management system 3-1 and the warehouse management system 3-s, the data configuration and the data name of the information stored in both systems may be different. Since the warehouse management system is provided by various companies and the like, the format of data may be different for each warehouse management system. Similarly, the data configuration of the slot information of the warehouse managed by the warehouse PC may be different for each warehouse PC as a target to be managed by the same warehouse management system. Therefore, the data configuration and the data name of the slot information transmitted from the warehouse management system to the arithmetic device 2 are not intended to be limited to the slot ID, the slot position, the slot size, the pick position, the pick order, and the pick zone ID, and data corresponding thereto may be included.

The converted warehouse information obtained by the data conversion processing executed in the processing of step St25 of FIG. 3 includes conversion slot information, passage information, wall information, region information, a pick list, and stock information. The slot information transmitted from the warehouse management system to the arithmetic device 2 may have a different data configuration for each warehouse management system or each warehouse PC. Therefore, when automatically generating the simulation model, the arithmetic device 2 generalizes (in other words, standardizes) the information by using the data conversion processing. Accordingly, it is possible to automatically generate the simulation model based on the generalized information from information acquired from any warehouse management system of the warehouse management systems 3-1 to 3-s.

The conversion slot information includes a conversion slot ID, a conversion slot position, a conversion slot size, and a conversion pick position as data. The conversion slot ID is a slot ID subjected to anonymization processing. The anonymization processing is processing of preventing information on a customer or the like from being acquired from the slot ID. An example of the conversion slot ID is an integer value such as “00001”. The conversion slot position is a slot position that has been corrected for the automatic generation of the simulation model. The conversion slot size represents a slot size in a distance unit system used in the simulation model. For example, the conversion slot size is represented by meters. The conversion pick position is a pick position that has been corrected in accordance with the correction of the slot position to the conversion slot position.

The passage information includes a passage ID, start point and end point positions, a passage width, and the presence or absence of one-way traffic restriction as data. The worker moves through a passage present in the warehouse and executes the work. The passage ID is an identifier of a passage. The start point and end point positions indicate a start point and an end point of the passage, and are represented by, for example, two-dimensional coordinates. The passage width indicates the width of the passage. The presence or absence of the one-way traffic restriction indicates whether the passage is one-way traffic.

The wall information includes a wall ID, start point and end point positions, a wall height, and visibility as data. The wall ID is an identifier of a wall present in the warehouse. The start point and end point positions indicate positions of ends corresponding to a start point and an end point of the wall in a horizontal direction, respectively, and are represented by, for example, two-dimensional coordinates. The wall height indicates the height of the wall. The visibility indicates whether to make the wall visible.

The region information includes three pieces of information, which are a standby region, a loading region, and a warehouse region, and each of the three pieces of information includes the start point and end point positions as data. The warehouse region defines a region of the entire simulation target warehouse generated as the simulation model. The standby region is a region for the worker to wait before the work is started. The loading region is a region for performing loading work for shipping one or more articles picked by the worker from the simulation target warehouse. The standby region and the loading region are parts of the warehouse region.

The pick list includes a pick list ID, the conversion slot ID, an item ID, and the number of pick items as data. Here, the item refers to an article stored in a slot. The pick list includes information indicating which article is picked from which shelf (slot) by the worker or the like. The worker or the like performs a picking work based on the pick list. The pick list ID is an identifier of the pick list. The item ID is an identifier of the article. The number of pick items indicates the number of articles to be picked.

The stock information includes the conversion slot ID, the item ID, and the number of stock items as data. The number of stock items indicates a stock quantity of articles before the execution of the simulation.

### Example of Simulation Model

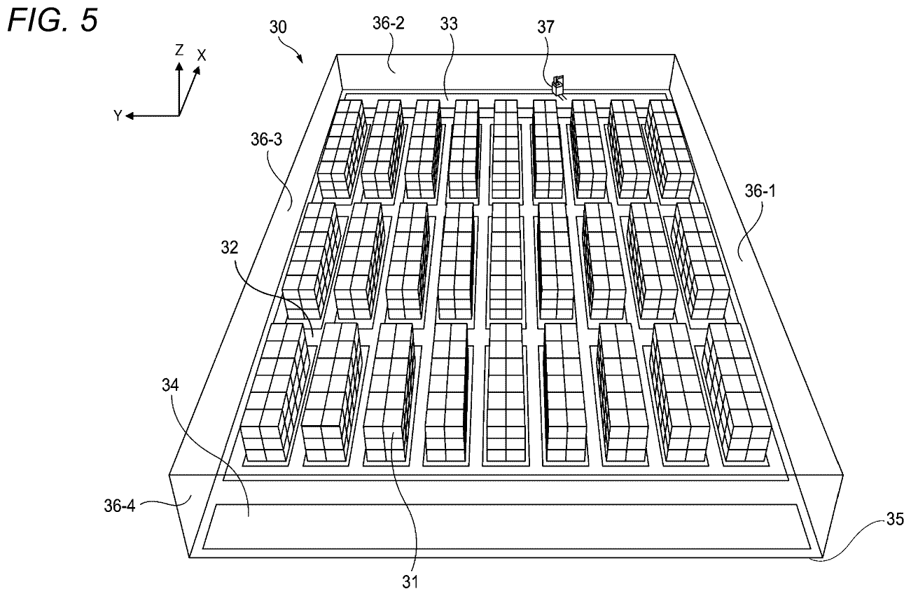

FIG. 5 illustrates a 3D model 30 of the warehouse generated in the cyber space based on the converted warehouse information. The 3D model 30 is obtained by visualizing the simulation target warehouse as the simulation model. The 3D model 30 includes a plurality of shelves 31, a plurality of passages 32, a standby region 33, a loading region 34, a warehouse region 35, a wall 36-1, a wall 36-2, a wall 36-3, a wall 36-4, and a worker 37. In the 3D model 30, the shelf 31 is generated based on the slot information. The shelf 31 includes a plurality of slots, and articles are stored in each slot based on the stock information. The passage 32 is generated based on the passage information. The standby region 33, the loading region 34, and the warehouse region 35 are generated based on the region information. The walls 36-1 to 36-4 are generated to surround the entire warehouse based on the wall information. The worker 37 works based on the pick list during the execution of the simulation. The worker 37 may be represented by a person or may be represented by a cargo handling vehicle such as a forklift as illustrated in FIG. 5. The 3D model 30 illustrated in FIG. 5 is an example, and the present invention is not limited thereto. Further, in the present embodiment, the description will be made using a three-dimensional coordinate system consisting of an X axis, a Y axis, and a Z axis, and the orientation of the three-dimensional coordinate system in each figure corresponds to that in the other figures. In each figure, an orientation of an arrow of the coordinate system illustrated in the figure is positive, and a direction opposite to the arrow is negative. The configuration of each axis is an example, and the present disclosure is not limited thereto.

### Processing of Warehouse Management System

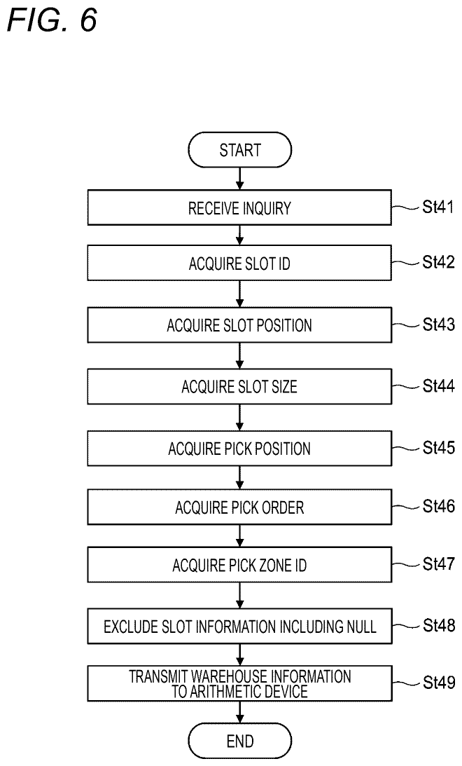

A flow of processing of the warehouse management system according to Embodiment 1 will be described with reference to FIG. 6. The warehouse management system receives an inquiry about the simulation target warehouse from the arithmetic device 2 (step St41).

The warehouse management system acquires the slot ID for the slot provided in the simulation target warehouse (step St42). The slot ID may be assigned to the slot by the warehouse management system.

The warehouse management system acquires the slot position for the slot provided in the simulation target warehouse (step St43). For example, when the slot is a rectangular parallelepiped, the slot position acquired here may be three-dimensional coordinates of the center of the slot or three-dimensional coordinates of one of six vertexes of the slot. Alternatively, it may be three-dimensional coordinates of each of the six vertexes of the slot. Which position of the slot is acquired as the slot position may be set in advance by the warehouse management system.

The warehouse management system acquires the slot size for the slot provided in the simulation target warehouse (step St44). The slot size may be defined in advance according to the type of the shelf or the like. For example, the slot size may be defined in advance based on the size of the shelf, the partition plate of the shelf, and the size of the shelf plate. Further, the slot size may be obtained by calculation based on the coordinates of the slot. For example, when the slot is a rectangular parallelepiped, the length of each side of the slot may be obtained based on the three-dimensional coordinates of the six vertexes of the slot.

The warehouse management system acquires the pick position for the slot provided in the simulation target warehouse (step St45). The pick position may be defined in advance for the slot. Further, the pick position may be determined corresponding to, for example, the slot position. For example, a position separated from the slot position by a predetermined distance in a positive or negative direction of the Y axis may be determined as the pick position.

The warehouse management system acquires the pick order for the slot provided in the simulation target warehouse (step St46). The pick order is defined in advance for the slots.

The warehouse management system acquires the pick zone ID for the slot provided in the simulation target warehouse (step St47). The pick zone ID is defined in advance for the slot. By the processing from step St42 to step St47, the warehouse management system can acquire the slot information of each slot provided in the simulation target warehouse.

The warehouse management system excludes slot information including NULL in the data (step St48). The data being NULL indicates a state in which the data does not contain a value. Here, the exclusion refers to preventing transmission to the arithmetic device 2. When data of at least one of the slot ID, the slot position, the slot size, the pick position, the pick order, and the pick zone ID of any slot is NULL, the slot information of the slot is excluded.

The warehouse management system transmits slot information of all slots obtained by executing the processing of steps St42 to St48 for all the slots of the simulation target warehouse to the arithmetic device 2 as the warehouse information (step St49). Then, this processing flow ends.

### Data Conversion Processing

A flow of the data conversion processing executed by the arithmetic device 2 according to Embodiment 1 will be described with reference to FIG. 7. At a start time of the processing flow illustrated in FIG. 7, the processing of step St49 of the warehouse management system illustrated in FIG. 6 is completed. The arithmetic device 2 acquires the warehouse information (see step St49 in FIG. 6) transmitted from the warehouse management system (step St51).

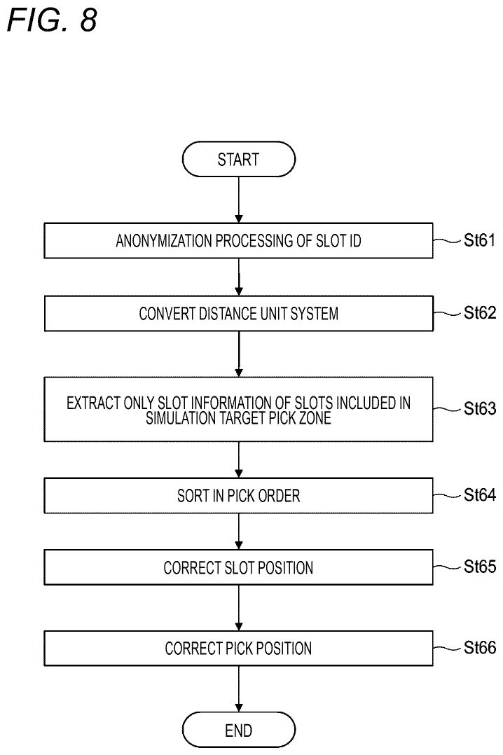

The arithmetic device 2 converts the slot information for each slot constituting the warehouse information acquired in step St51, and generates the conversion slot information (step St52). Details of this step will be described later with reference to FIG. 8.

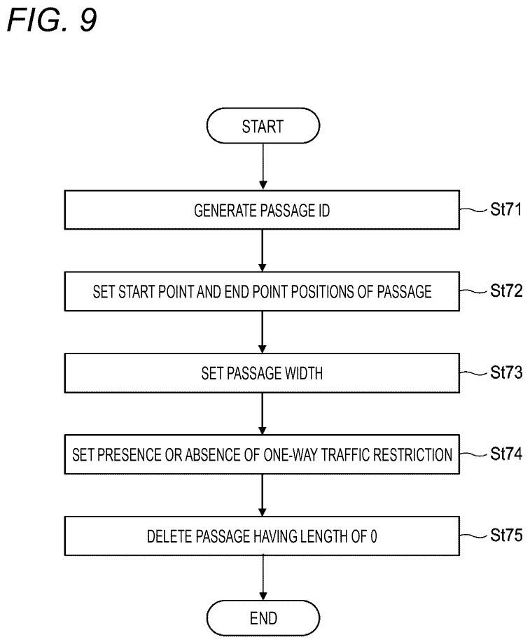

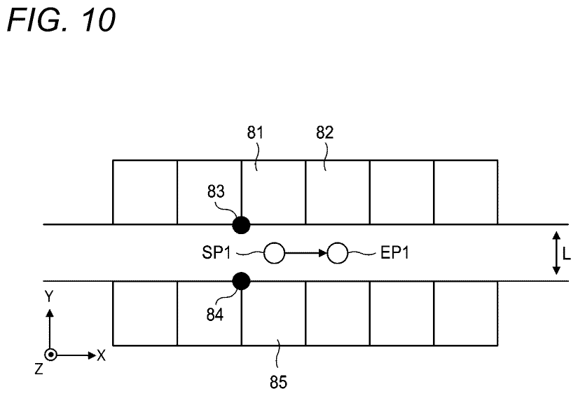

The arithmetic device 2 generates passage information of the passages present in the simulation target warehouse based on the conversion slot information generated in step St52 (step St53). Details of this step will be described later with reference to FIGS. 9 and 10.

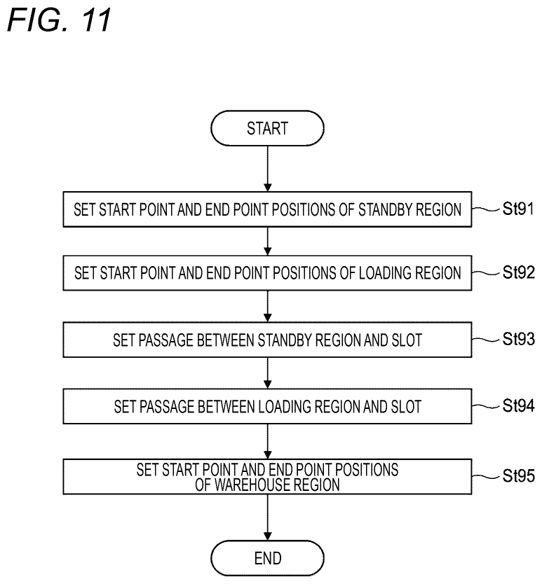

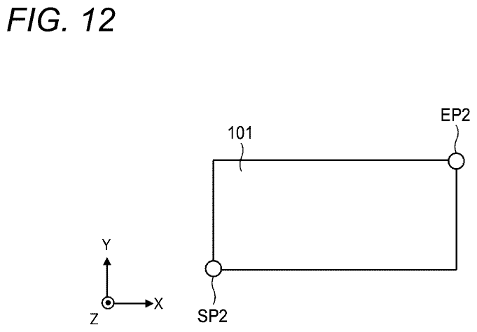

The arithmetic device 2 generates region information of various regions present in the simulation target warehouse based on the conversion slot information generated in step St52 and the passage information generated in step St53 (step St54). Details of this step will be described later with reference to FIGS. 11 and 12.

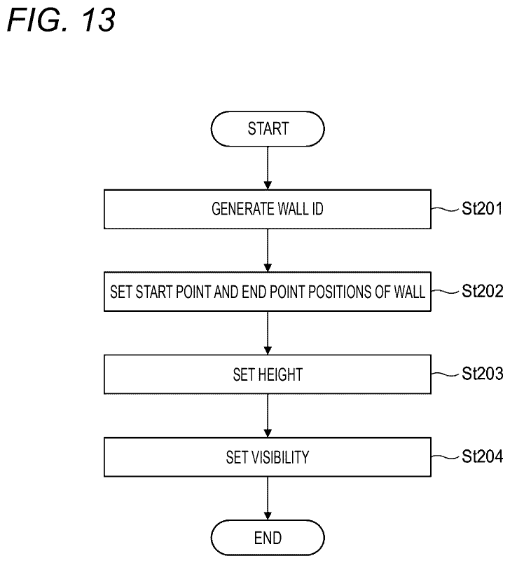

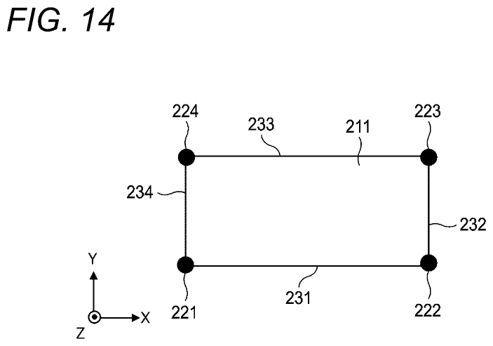

The arithmetic device 2 generates the wall information of one or more walls present in the simulation target warehouse based on the region information generated in step St54 (step St55). Details of this step will be described later with reference to FIGS. 13 and 14.

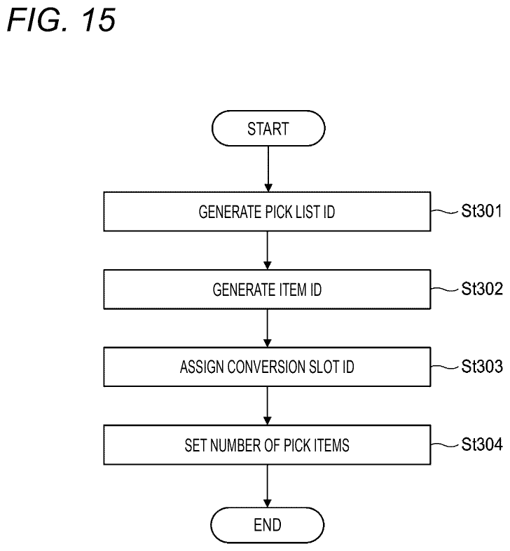

The arithmetic device 2 generates, based on the conversion slot information generated in step St52, a pick list including one or more slots to be picked by the worker in the simulation target warehouse (step St56). Details of this step will be described later with reference to FIG. 15.

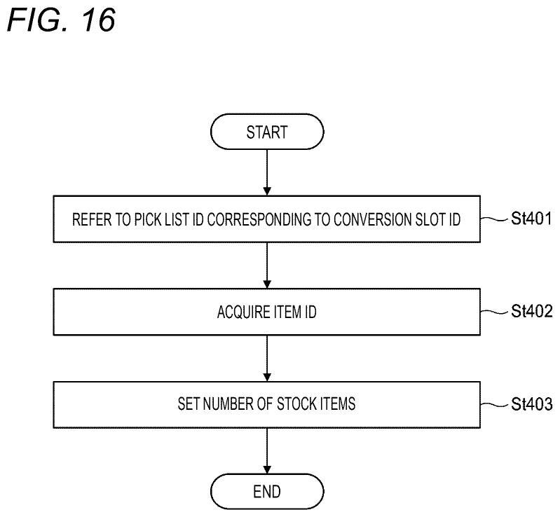

The arithmetic device 2 generates, based on the pick list generated in step St56, stock information of the articles stored in the slot constituting the pick list of the simulation target warehouse (step St57). Then, this processing flow ends. Details of this step will be described later with reference to FIG. 16.

### Slot Information Conversion

A flow of the slot information conversion processing executed by the arithmetic device 2 according to Embodiment 1 will be described with reference to FIG. 8. At a start time of the processing flow illustrated in FIG. 8, the arithmetic device 2 has acquired the warehouse information transmitted from the warehouse management system.

The arithmetic device 2 executes the anonymization processing of the slot ID among the slot information for each slot constituting the warehouse information acquired in step St51 (step St61). By the anonymization processing, the slot ID becomes the conversion slot ID. The slot ID may be converted to a consecutive integer value such as “00001”, “00002”, and “00003”.

The arithmetic device 2 converts the data including the unit of the distance in the slot information for each slot constituting the warehouse information acquired in step St51 into the distance unit system used in the simulation model (see the 3D model 30 in FIG. 5) (step St62). For example, when the slot size is represented by inches and meters are used in the simulation model, the unit of the slot size is converted into meters by the processing of step St62. Accordingly, the slot size becomes the conversion slot size. When the processing of step St62 is completed, the slot information includes the conversion slot ID, the slot position, the conversion slot size, the pick position, the pick order, and the pick zone ID.

The arithmetic device 2 extracts only the slot information of the slots provided in a pick zone in the simulation target warehouse among the slot information for each slot constituting the warehouse information acquired in step St51 (step St63). For example, it is assumed that the pick zone ID of the slot is “0001” in a simulation target pick zone. When the warehouse information transmitted from the warehouse management system includes the slot information with the pick zone ID “0001” and the slot information with the pick zone ID “0002”, only the slot information with the pick zone ID “0001” is extracted. Extraction refers to being handled in the subsequent processing of the arithmetic device 2. The simulation target pick zone may be set in advance by the user or the like.

The arithmetic device 2 sorts the slot information extracted in the processing of step St63 in the pick order (step St64). In the subsequent processing of the arithmetic device 2, the slot information is sorted in the pick order.

The arithmetic device 2 corrects the slot position in accordance with a reference point in the simulation model (step St65). For example, when an origin of the three-dimensional coordinate system is the reference point, the arithmetic device 2 corrects all the slot positions of the simulation target slots such that a slot position of a slot having the smallest distance from the origin among the simulation target slots is positioned at the origin. For example, when the slot position of the slot having a smallest distance from the origin has an X coordinate of 100, a Y coordinate of 200, and a Z coordinate of 0, the X coordinate and the Y coordinate of all the slot positions of the simulation target slots are corrected to −100 and −200, respectively. Accordingly, the slot position becomes the conversion slot position.

The arithmetic device 2 performs correction similar to the correction of the slot position performed in step St65 on the pick position (step St66). As in the example in the description of step St65, when the X coordinate and the Y coordinate of the slot position are corrected to −100 and −200, respectively, the arithmetic device 2 corrects an X coordinate and a Y coordinate of the pick position to −100 and −200, respectively. Accordingly, the pick position becomes the conversion pick position. Then, this processing flow ends.

When the processing from step St61 to step St66 is completed, the slot information includes the conversion slot ID, the conversion slot position, the conversion slot size, the conversion pick position, the pick order, and the pick zone ID. In the subsequent processing, the arithmetic device 2 generates information necessary for the automatic generation of the simulation model and execution of the simulation based on the conversion slot information including the conversion slot ID, the conversion slot position, the conversion slot size, and the conversion pick position. The conversion slot information is sorted in the pick order.

The conversion slot information may be generated as, for example, a comma separated values (hereinafter, referred to as “CSV”) file. The CSV file may include data for each slot (for each conversion slot ID).

### Generation of Passage Information

Passage information generation processing executed by the arithmetic device 2 according to Embodiment 1 will be described with reference to FIGS. 9 and 10. FIG. 9 is a flowchart of the passage information generation processing.

The arithmetic device 2 generates the passage ID (step St71). The passage ID may be a consecutive integer value such as “00001”, “00002”, and “00003”.

The arithmetic device 2 sets the start point and end point positions of the passage based on the pick order of the slot and the conversion pick position acquired in step St66 (step St72). The start point and end point positions mean the coordinates of the start point and the end point. FIG. 10 is a schematic diagram for illustrating an example of generation of passage information. An example of setting the start point and end point positions of the passage will be described with reference to FIG. 10. Here, the start point and end point positions of the passage connecting a slot 81 to a slot 82 illustrated in FIG. 10 are set. The passage connecting the slot 81 to the slot 82 is a passage through which a worker or the like can move for work in the slot 81 and the slot 82. The pick order of the slot 81 and the slot 82 is continuous. For example, the pick order of the slot 81 is 1, and the pick order of the slot 82 is 2.

In the example of FIG. 10, a start point SP1 and an end point EP1 of the passage are set to the XY coordinates of the conversion pick position of the slot 81 and the XY coordinates of the conversion pick position of the slot 82, respectively. The conversion pick position of the slot 81 has an X coordinate of 10 and a Y coordinate of 10. The conversion pick position of the slot 82 has an X coordinate of 12 and a Y coordinate of 10. As described above, the start point is set based on a conversion pick position of a slot having an earlier pick order among the slots having the consecutive pick order, and the end point is set based on a conversion pick position of a slot having a later pick order. For example, an end point of the passage having the passage ID “00001” and a start point of the passage having the passage ID “00002” may be at the same position, and the passage of the entire warehouse is generated by connecting the passages in this way. The passage may be set in advance by the user or the like such that the passage is generated on an XY plane whose Z coordinate is equal to a Z coordinate of the reference point in the simulation model. The Z coordinate of the XY plane in which the passage is generated may be set in advance by the user or the like. The arithmetic device 2 associates the start point and end point positions of the set passage with the passage ID generated in step St71.

The arithmetic device 2 sets the width of the passage based on the conversion slot position acquired in step St65 and the start point and end point positions of the passage set in step St72 (step St73). The width of the passage may be set to, for example, a distance between slots sandwiching the start point or the end point set in step St72. For example, in the example of FIG. 10, a distance L between the slot 81 and a slot 85 facing the slot 81 is set as the width of the passage. Here, the distance between the slot 81 and the slot 85 is equal to a distance between a point 83 and a point 84. The point 83 is one of vertexes of the slot 81, and the point 84 is one of vertexes of the slot 85. The point 83 and the point 84 are on the same XY plane. For example, when an X coordinate of the point 83 is 9 and a Y coordinate is 11, and an X coordinate of the point 84 is 9 and a Y coordinate is 9, a distance between the point 83 and the point 84 is 2. At this time, the width of the passage may be set to two meters.

The arithmetic device 2 sets the presence or absence of the one-way traffic restriction of the passage for each passage generated by executing the processing of steps St71 to St73 (step St74). In the passage in which the one-way traffic restriction is set, the passage is one-way traffic from the start point to the end point. For example, in the example of FIG. 10, when the passage formed by the start point SP1 and the end point EP1 is restricted to one-way traffic, the worker or the like can move in the direction from the start point SP1 to the end point EP1, but cannot move in the opposite direction. When the passage is not restricted to one-way traffic, the worker or the like can move from the end point EP1 to the start point SP1.

The arithmetic device 2 deletes a passage having a length of 0 among all the passages generated by executing the processing of steps St71 to St74 (step St75). Here, the length refers to a distance between the start point and the end point. For example, in the example of FIG. 10, the distance between the start point SP1 and the end point EP1 is 2. Examples of the case where the length of the passage is 0 include a case where the start point and the end point are set to the same position (more specifically, a position where the orientation at the time of picking is different but the X coordinate and the Y coordinate are the same) based on the conversion pick position and the pick order such that the pick order of the slot 81 is 1 and a pick order of the slot 85 is 2. When the processing of step St75 is completed, the arithmetic device 2 ends this processing flow.

Unlike the example illustrated in FIG. 10, the start and end points may be set in positions where the worker or the like cannot move in a straight line connecting them. For example, there is a case where a slot is present on a straight line connecting the start point to the end point. In this case, a passage is generated so as to avoid the slot. As described above, the length may not be a shortest distance between the start point and the end point.

The passage information may be generated as, for example, a CSV file. The CSV file may include data for each passage (for each passage ID).

### Generation of Region Information

Region information generation processing executed by the arithmetic device 2 according to Embodiment 1 will be described with reference to FIGS. 11 and 12. FIG. 11 is a flowchart of the region information generation processing.

The arithmetic device 2 sets the start point and end point positions of the standby region (step St91). FIG. 12 is a schematic diagram for illustrating an example of the generation of the region information. For example, the arithmetic device 2 sets a start point SP2 and an end point EP2 as the start point and the end point of the standby region, respectively. At this time, a region 101 inside a quadrangle having the start point SP2 and the end point EP2 as opposite vertexes may be defined as the standby region. The region 101 may also include sides of the quadrangle. For example, when an X coordinate and a Y coordinate of SP2 are 10 and 20, respectively, and an X coordinate and a Y coordinate of EP2 are 60 and 40, respectively, the XY plane in which the X coordinate is from 10 to 60 and the Y coordinate is from 20 to 40 is defined as the standby region. A Z coordinate of the standby region may be set in advance by the user or the like. For example, the standby region may be set in advance as a region on the XY plane having a Z coordinate of 0, and the Z coordinate of the standby region may be set in advance as being equal to the Z coordinate of the reference point of the simulation model. This similarly applies to the loading region and the warehouse region to be described later.

The arithmetic device 2 sets the start point and end point positions of the loading region in a way similar to the processing of step St91 (step St92). The loading region is defined by setting the start point and end point positions of the loading region.

The arithmetic device 2 sets a passage between the standby region and the slot based on the conversion slot position acquired in step St65 and the standby region defined in step St91 such that the worker or the like can move from the standby region to the work target slot to start the work such as picking (step St93). The passage may be set to connect the standby region to the slot having a shortest distance from the standby region, or may be set to connect the standby region to the slot that is the first in the pick order. The passage may be set by a series of processing illustrated in FIG. 9.

The arithmetic device 2 sets a passage between the loading region and the slot based on the conversion slot position acquired in step St65 and the loading region defined in step St92 such that the worker or the like who has completed the work such as picking can move to the loading region for shipment preparation (step St94). The passage may be set to connect the loading region to the slot having a shortest distance from the loading region, or may be set to connect the loading region to the slot that is the last in the pick order. The passage may be set by a series of processing illustrated in FIG. 9.

The arithmetic device 2 sets the start point and end point positions of the warehouse region in a way similar to the processing of step St91 (step St95). The warehouse region is a region serving as a base of the simulation model generated in the cyber space. Therefore, the slot, the passage, the standby region, and the loading region are provided in the range of the X coordinate and the Y coordinate defining the warehouse region. When the processing of step St95 is completed, the arithmetic device 2 ends this processing flow.

The region information may be generated as, for example, a CSV file. The CSV file may include the start point and end point positions of each of the standby region, the loading region, and the warehouse region. The data of the passage set in the processing of steps St93 and St94 may be added to a file (for example, the CSV file) including passage information.

### Generation of Wall Information

Wall information generation processing executed by the arithmetic device 2 according to Embodiment 1 will be described with reference to FIGS. 13 and 14. FIG. 13 is a flowchart of the wall information generation processing.

The arithmetic device 2 generates the wall ID (step St201). The wall ID may be a consecutive integer value such as “00001”, “00002”, and “00003”.

The arithmetic device 2 sets start point and end point positions of four walls surrounding the entire warehouse based on the warehouse region defined in step St95 (step St202). FIG. 14 is a schematic diagram for illustrating an example of the generation of the wall information. Here, the region 211 is a warehouse region. Four vertexes of the region 211 are a point 221, a point 222, a point 223, and a point 224. At this time, a start point and an end point of a wall 231 may be set to the point 221 and the point 222, respectively. A start point and an end point of a wall 232 may be set to the point 222 and the point 223, respectively. A start point and an end point of a wall 233 may be set to the point 223 and the point 224, respectively. A start point and an end point of a wall 234 may be set to the point 224 and the point 221, respectively. The point 221, the point 222, the point 223, and the point 224 are points on the same XY plane. The wall is defined by setting the start point and end point positions of the wall. For example, when the point 221 has an X coordinate of 0 and a Y coordinate of 0, and the point 222 has an X coordinate of 60 and a Y coordinate of 0, the wall 231 is defined as an XZ plane having an X coordinate of 0 to 60 and a Y coordinate of 0. At the time of setting the start point and end point positions of the wall, the Z coordinate of the wall may not be limited. The arithmetic device 2 associates the set start point and end point positions of the wall with the wall ID generated in step St201.

The arithmetic device 2 sets the height of the wall defined in step St202 (step St203). The arithmetic device 2 may set the height of the wall to, for example, 1 meter. In the example of FIG. 14, the heights of the wall 231, the wall 232, the wall 233, and the wall 234 may be set to 1 meter. For example, the heights of the four walls may be set separately or may be set collectively. A relationship between the height of the wall and the coordinates may be set in advance by the user or the like. For example, one meter may be set to correspond to one of a change amount of the coordinates. The Z coordinate of the wall may also be set by setting the height of the wall. For example, when the height of the wall 231 is set to 1 meter, the wall 231 may be defined as the XZ plane having the X coordinate of 0 to 60, the Y coordinate of 0, and a Z coordinate of 0 to 100. A Z coordinate of a bottom side of the wall may be set to 0 in advance, or the Z coordinate of the reference point in the simulation model may be set to the Z coordinate of the bottom side of the wall in advance.

The arithmetic device 2 sets the visibility of the wall defined in step St202 (step St204). When the wall is set to be visible, the user can visually recognize the wall in the generated simulation model. When the processing of step St204 is completed, the arithmetic device 2 ends this processing flow.

The wall information may be generated as, for example, a CSV file. The CSV file may include data of each of the four walls surrounding the entire warehouse.

### Generation of Pick List

FIG. 15 is a flowchart of pick list generation processing executed by the arithmetic device 2 according to Embodiment 1. The pick list is minimum information necessary for executing the simulation using the generated simulation model.

The arithmetic device 2 generates the pick list ID (step St301). The pick list ID may be a consecutive integer value such as “0001”, “0002”, and “0003”.

The arithmetic device 2 generates the item ID (step St302). The item ID may be a consecutive integer value such as “0001”, “0002”, and “0003”. For example, the arithmetic device 2 associates the item ID “0002” with the pick list ID “0001”.

The arithmetic device 2 assigns a conversion slot ID to each pick list ID generated in step St301 (step St303). Here, the conversion slot ID may be randomly allocated. By randomly allocating the conversion slot ID, optimization of the warehouse work can be examined by executing the simulation. For example, the arithmetic device 2 assigns the conversion slot ID “00001” to the pick list ID “0001”. At this time, since the item ID “0002” is associated with the pick list ID “0001”, articles having the item ID “0002” are picked from the slot having the conversion slot ID “00001” when the simulation is executed.

The arithmetic device 2 sets the number of pick items for each pick list ID generated in step St301 (step St304). For example, the arithmetic device 2 sets the number of pick items to 10 corresponding to the pick list ID “0001”. When the processing of step St304 is completed, the arithmetic device 2 ends this processing flow.

A pick list is generated by the series of processing illustrated in FIG. 15. One pick list includes one pick list ID, one conversion slot ID, one item ID, and one number of pick items. For example, when the pick list ID, the conversion slot ID, the item ID, and the number of pick items provided in the pick list are “0001”, “00001”, “0002”, and “10”, respectively, the pick list means the following contents. That is, the worker or the like picks only 10 articles with the item ID “0002” stored in the slot with the conversion slot ID “00001” based on the pick list with the pick list ID “0001”.

All the generated pick lists may be collected as, for example, a pick list file. The pick list file may be, for example, a CSV file.

### Generation of Stock Information

FIG. 16 is a flowchart of stock information generation processing executed by the arithmetic device 2 according to Embodiment 1. The arithmetic device 2 generates stock information based on the pick list generated by the series of processing illustrated in FIG. 15. According to this flow, the number of articles stored in the slot can be generated for each slot. In the description of this flow, stock information is generated based on the pick list having the pick list ID “0001” exemplified in the description of FIG. 15.

The arithmetic device 2 refers to the pick list ID corresponding to the conversion slot ID (step St401). For example, the arithmetic device 2 refers to the pick list ID “0001” corresponding to the conversion slot ID “00001”. Accordingly, the arithmetic device 2 can acquire the item ID and the number of items provided in the pick list having the pick list ID “0001”.

The arithmetic device 2 acquires the item ID corresponding to the pick list ID referred to in step St401 (step St402). For example, the arithmetic device 2 acquires the item ID “0002” corresponding to the pick list ID “0001”. The arithmetic device 2 sets the acquired item ID as data of the stock information.

The arithmetic device 2 sets the number of stock items for each item ID acquired in step St402 (step St403). For example, the arithmetic device 2 sets the number of stock items of the articles having the item ID “0002” to 10. When the simulation is executed according to the pick list having the pick list ID “0001” exemplified in the description of FIG. 15, the number of articles having the item ID “0002” stored in the slot having the conversion slot ID “00001” is as follows. That is, since the number of stock items before the execution of the simulation is 10 and only 10 items are picked in the simulation, the remaining number after the execution of the simulation is 0. The arithmetic device 2 may set the number of stock items so as to prevent an error from occurring due to stock shortage when the simulation is executed. For example, the number of stock items of a certain conversion slot ID may be set in advance by the user to be equal to or less than the number of pick items of the conversion slot ID. When the processing of step St403 is completed, the arithmetic device 2 ends this processing flow.

The stock information may be generated as, for example, a CSV file. The CSV file may include a stock quantity for each slot (for each conversion slot ID).

### Generation of Simulation Model and Simulation Execution

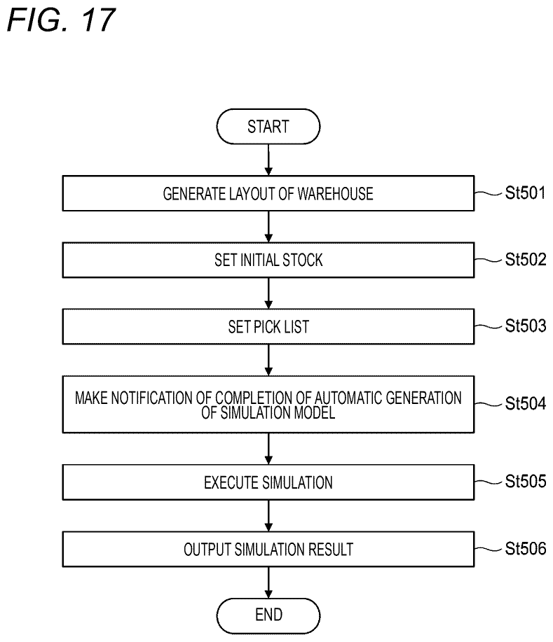

FIG. 17 is a flowchart of simulation model generation and simulation execution processing executed by the arithmetic device 2 according to Embodiment 1. At a start time of this flow, the arithmetic device 2 has completed the series of processing illustrated in FIG. 7. That is, the data conversion processing is completed. The arithmetic device 2 receives an instruction to automatically generate the simulation model from the user.

The arithmetic device 2 generates the layout of the warehouse based on the conversion slot information, the passage information, the wall information, and the region information (step St501). Accordingly, the 3D model simulating the warehouse in the cyber space is generated (see FIG. 5).

The arithmetic device 2 sets an initial stock of the articles stored in the slot based on the stock information (step St502). Depending on the stock information of the slot, nothing may be stored in the slot. Depending on the stock information and the pick list, nothing may be stored in the slot after the execution of the simulation. A display mode of the slot generated in the cyber space may be set in advance such that the user can visually recognize that some article is stored in the slot. For example, the slot in which the article is stored and the slot in which the article is not stored may be displayed in different colors, or the stock quantity may be displayed in the slot.

The arithmetic device 2 sets one or a plurality of pick lists to be followed by the worker or the like in the simulation (step St503). Here, the arithmetic device 2 may set the simulation pick list by reading a pick list file in which a plurality of pick lists are collected.

When the automatic generation of the simulation model is completed, the arithmetic device 2 notifies the user of the completion (step St504).

When receiving the instruction to execute the simulation from the user, the arithmetic device 2 executes the simulation (step St505). During the execution of the simulation, for example, it may be possible for the user to confirm how the worker or the like moves on the simulation model or performs the picking work.

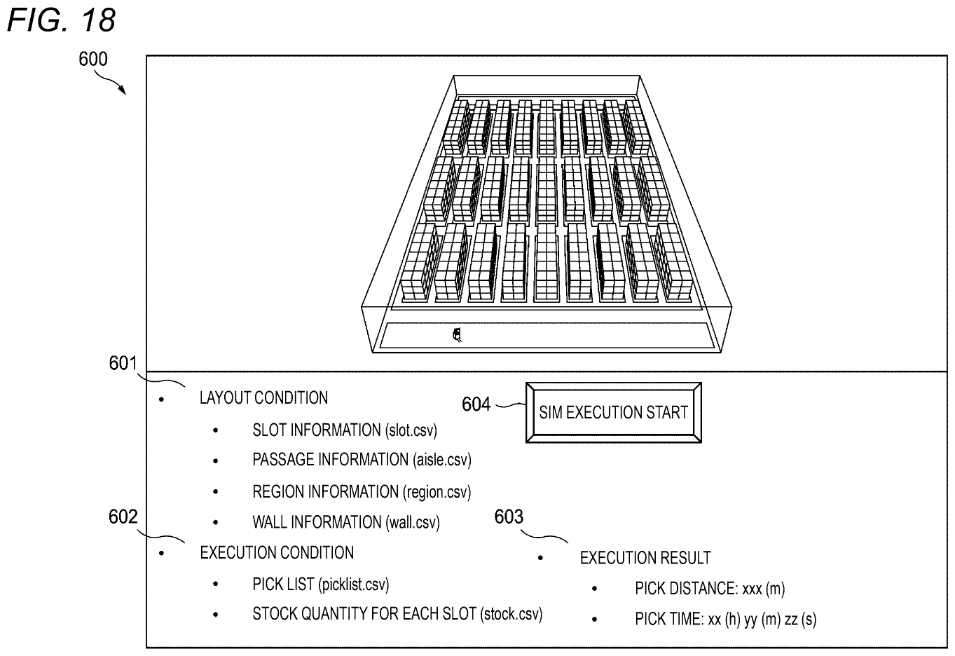

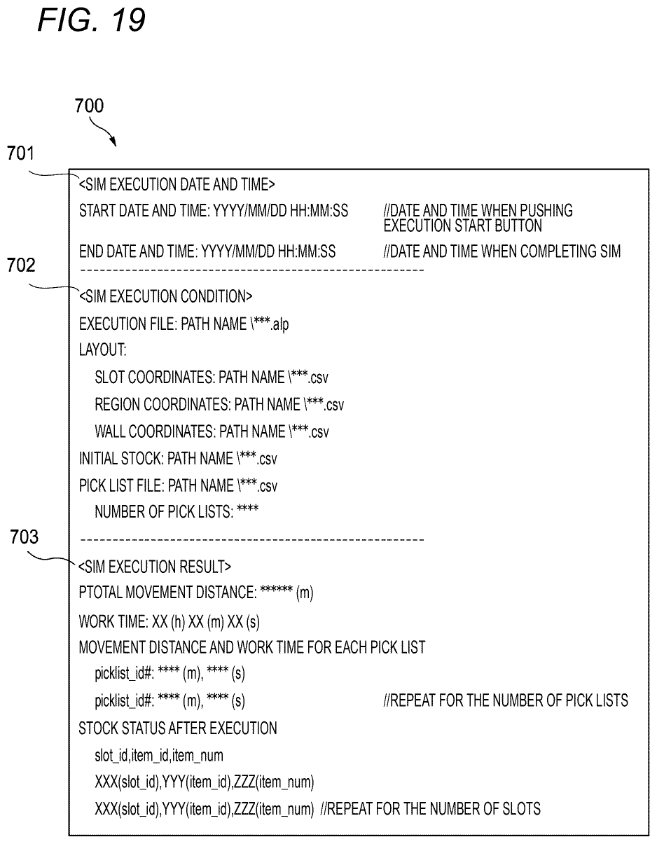

When the simulation is completed, the arithmetic device 2 outputs the simulation result (step St506). Then, this processing flow ends. The output simulation results will be described later with reference to FIGS. 18 and 19.

### Example of Simulation Result

FIG. 18 is a schematic diagram illustrating an example of a simulation result according to Embodiment 1. A window 600 illustrated in FIG. 18 is displayed on, for example, the display (not illustrated). A simulation model is displayed in the window 600. In the window 600, a layout condition 601, an execution condition 602, an execution result 603, and a simulation execution button 604 are displayed. Here, “SIM” means simulation. The window 600 illustrated in FIG. 18 is merely an example of the simulation result, and is not intended to limit an output content of the simulation result.

The layout condition 601 indicates layout conditions. In the example of FIG. 18, a slot is generated based on a CSV file “slot.csv”. A passage is generated based on a CSV file “aisle.csv”. Each region is generated based on a CSV file “region.csv”. Further, a wall is generated based on a CSV file “wall.csv”.

The execution condition 602 indicates execution conditions of the simulation. In the example of FIG. 18, the simulation is executed based on a CSV file “picklist.csv”. An initial stock quantity of the articles stored in each slot is set based on the CSV file “stock.csv”.

An execution result 603 indicates execution results of the simulation. Here, a pick distance indicates a distance by which the worker or the like moves in the simulation. A pick time indicates a time from the start to the completion of the work by the worker or the like in the simulation.

The user may execute the simulation by clicking the simulation execution button 604 with, for example a mouse (not illustrated). Alternatively, the simulation may be executed by operating a keyboard or the like (not illustrated).

FIG. 19 is a schematic diagram illustrating an example of the simulation result according to Embodiment 1. The arithmetic device 2 may output the simulation result as a text file 700 illustrated in FIG. 19.

In the example of FIG. 19, a simulation execution date and time 701, a simulation execution condition 702, and a simulation execution result 703 are described in the text file 700. The text file 700 illustrated in FIG. 19 is merely an example of the simulation result, and is not intended to limit the output content of the simulation result.

The simulation execution date and time 701 describes a date and time when a button for executing the simulation, such as the simulation execution button 604 illustrated in FIG. 18, is pressed. Further, the simulation execution date and time 701 describes the date and time when the simulation is completed.

In the simulation execution condition 702, a file for executing the simulation is described. The example of FIG. 19 illustrates that the simulation is executed by an ALP file “***.alp”. The type of a simulation execution file is not limited thereto. The simulation execution condition 702 describes the number of pick lists in addition to description corresponding to the layout condition 601 and the execution condition 602 illustrated in FIG. 18.

In the simulation execution result 703, a distance by which the worker or the like moves in the simulation is described as a total movement distance. In addition, a time from the start to the completion of the work by the worker or the like in the simulation is described as a work time. Further, the movement distance and the work time for each pick list and the stock status for each slot after the execution of the simulation are described.

### Modification of Embodiment 1

In the above embodiment, the pick list in which the pick list ID is “0001”, the conversion slot ID is “00001”, the item ID is “0002”, and the number of pick items is 10 has been described as an example. At this time, the item ID of a pick list different from this pick list may be “0002”. For example, a pick list in which the pick list ID is “0002”, the conversion slot ID is “00002”, the item ID is “0002”, and the number of pick items is 10 may be generated. The user or the like may set in advance how many pick lists having the same item ID are permitted.

Accordingly, it is possible to perform simulation in consideration of a case where the same articles are stored in a plurality of slots.

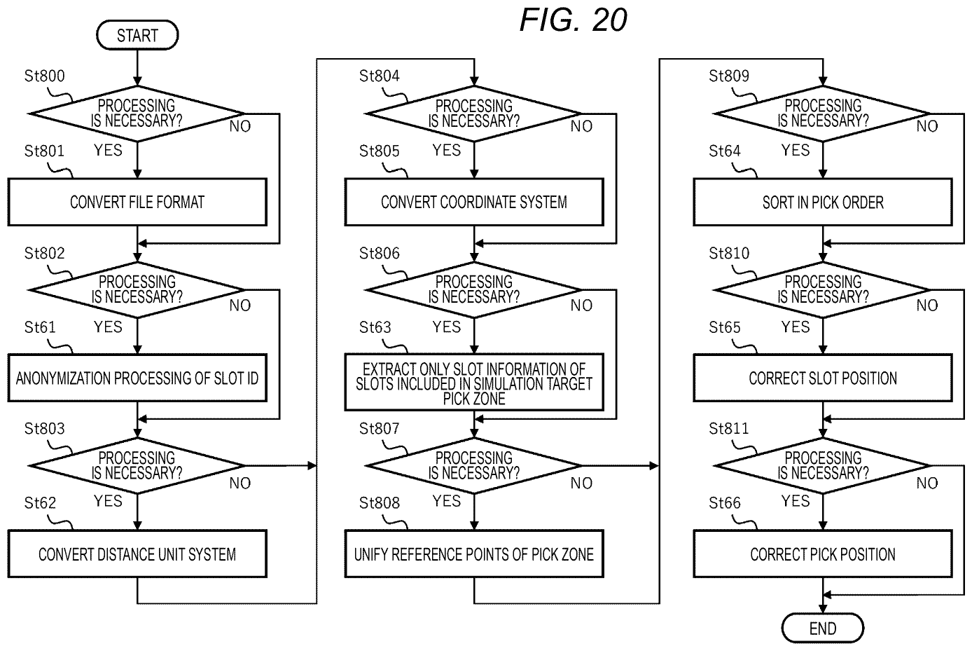

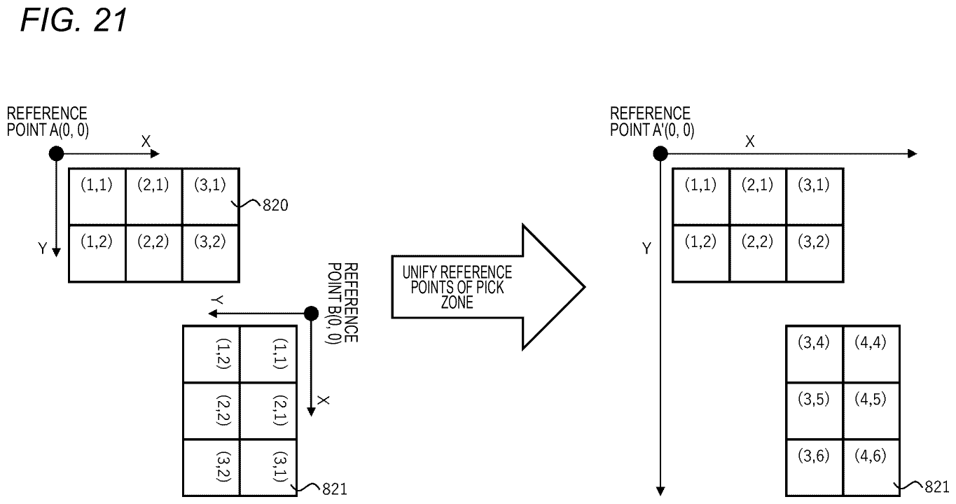

Further, in the above embodiment, the arithmetic device 2 makes it possible to automatically generate the simulation model even when the slot information is acquired from any warehouse management system by standardizing the slot information by the data conversion processing. When converting the slot information, the arithmetic device 2 may determine whether to perform the data conversion processing on the slot information. This is because, for example, slot information of a specific warehouse acquired from a specific warehouse management system can be used to generate a simulation model without the data conversion processing. Further, when converting the slot information, the arithmetic device 2 may perform conversion of a file format, conversion of the coordinate system, or unification of reference points of the pick zone in addition to each processing illustrated in FIG. 8. This will be described below with reference to FIGS. 20 and 21.

FIG. 20 is a flowchart of slot information conversion processing according to a modification of Embodiment 1. At a start time of the processing flow illustrated in FIG. 20, the arithmetic device 2 has acquired the warehouse information transmitted from the warehouse management system. The arithmetic device 2 receives the designation of the warehouse from the user in the processing of step St21 illustrated in FIG. 3. Therefore, the arithmetic device 2 can determine by which manufacturer's warehouse management system the acquired warehouse information is managed and which user's warehouse the acquired warehouse information belongs to.

Processing similar to the processing of the flowchart illustrated in FIG. 8 is denoted by the same reference numerals, and the description thereof may be omitted or simplified.

Based on the acquired warehouse information, in other words, the file format of the slot information and the file format used in the slot information conversion processing, the arithmetic device 2 determines whether the conversion processing of the file format of the slot information is necessary (step St800). When the file format of the acquired slot information is different from the file format used in the slot information conversion processing, the arithmetic device 2 determines that the processing of converting the file format of the slot information into the file format used in the slot information conversion processing is necessary.

More precisely, the arithmetic device 2 may perform the determination in step St800 based on which user's warehouse the acquired warehouse information belongs to and by which manufacturer's warehouse management system the acquired slot information is managed. This is because the arithmetic device 2 can grasp information such as a file format or the distance unit system of the slot information if it is possible to determine which user's warehouse the slot information belongs to and by which manufacturer's warehouse management system the slot information is managed. This similarly applies to any of the determination processing in this flowchart. For example, when acquiring the slot information of the specific warehouse managed by the specific warehouse management system, the arithmetic device 2 can determine that the conversion processing of the file format is necessary but the anonymization processing of the slot ID and the sorting of the pick order are not necessary based on which manufacturer's system the warehouse management system is and which user's warehouse the warehouse is.

When it is determined that the conversion processing of the file format of the acquired slot information is not necessary (step St800: NO), the arithmetic device 2 advances the processing to step St802.

When it is determined that the conversion processing of the file format of the acquired slot information is necessary (step St800: YES), the arithmetic device 2 converts the file format of the slot information into a file format used in the slot information conversion processing (step St801). For example, the arithmetic device 2 converts a JavaScript Object Notation (hereinafter, referred to as “JSON”) file acquired as the slot information into a CSV file.

Next, the arithmetic device 2 determines whether the anonymization processing of the slot ID is necessary (step St802). When it is determined that the anonymization processing of the slot ID is not necessary (step St802: NO), the arithmetic device 2 advances the processing to step St803. When it is determined that the anonymization processing of the slot ID is necessary (step St802: YES), the arithmetic device 2 executes the anonymization processing of the slot ID (step St61).

Next, the arithmetic device 2 determines whether the conversion processing of the distance unit system is necessary (step St803). When it is determined that the conversion processing of the distance unit system is not necessary (step St803: NO), the arithmetic device 2 advances the processing to step St804. When it is determined that the conversion processing of the distance unit system is necessary (step St803: YES), the arithmetic device 2 executes the conversion processing of the distance unit system (step St62).

Next, the arithmetic device 2 determines whether conversion processing of the coordinate system is necessary (step St804). When the coordinate system of the acquired slot information is different from the coordinate system used in the simulation model, the arithmetic device 2 converts the coordinate system of the slot information into the coordinate system used in the simulation model. For example, the arithmetic device 2 converts a right-handed coordinate system into a left-handed coordinate system. Further, for example, the arithmetic device 2 converts a geographic coordinate system representing a position by latitude and longitude into an orthogonal coordinate system including an X axis and a Y axis.

When it is determined that the conversion processing of the coordinate system is not necessary (step St804: NO), the arithmetic device 2 advances the processing to step St806. When it is determined that the coordinate system conversion processing is necessary (step St804: YES), the arithmetic device 2 executes the conversion processing of the coordinate system (step St805).

Next, the arithmetic device 2 determines whether processing of extracting only slot information of slots provided in a simulation target pick zone among the acquired slot information is necessary (step St806). When it is determined that the processing of extracting only the slot information of the slots provided in the simulation target pick zone among the acquired slot information is not necessary (step St806: NO), the arithmetic device 2 advances the processing to step St807. When it is determined that the processing of extracting only the slot information of the slots provided in the simulation target pick zone among the acquired slot information is necessary (step St806: YES), the arithmetic device 2 extracts only the slot information of the slots provided in the simulation target pick zone among the acquired slot information (step St63).

Next, the arithmetic device 2 determines whether processing of unifying the reference points of the pick zones is necessary (step St807). When a plurality of reference points are present in the simulation target pick zone, the arithmetic device 2 unifies the plurality of reference points into one reference point. Here, this will be described in detail with reference to FIG. 21.

FIG. 21 is a schematic diagram for illustrating the unification of the reference points of the pick zone according to the modification of Embodiment 1. In order to simplify the description, the example of FIG. 21 will be described using a two-dimensional coordinate system including an X axis and a Y axis. As illustrated in FIG. 21, when a reference point A(0, 0) and a reference point B(0, 0) are present in the pick zone, slots having the same coordinates, such as a slot 820 and a slot 821, are present. When the reference point A(0, 0) and the reference point B(0, 0) are present in the pick zone, the coordinates of the slot 820 and the slot 821 are both (3, 1).

When unifying the plurality of reference points in the pick zone, the arithmetic device 2 unifies the plurality of reference points to a specific reference point among the plurality of reference points. In the example of FIG. 21, the arithmetic device 2 unifies the reference point A and the reference point B to the reference point A′. Accordingly, the reference point in the pick zone is only one reference point A′ obtained by unifying the reference point A and the reference point B. Accordingly, the pick zone does not include slots having the same coordinates. For example, when the reference points of the pick zone are unified, the coordinates of the slot 821 are (4, 6).

When it is determined that the processing of unifying the reference points of the pick zone is not necessary (step St807: NO), the arithmetic device advances the processing to step St809. When it is determined that the processing of unifying the reference points of the pick zone is necessary (step St807: YES), the arithmetic device 2 executes the processing of unifying the reference points of the pick zone (step St808).

Next, the arithmetic device 2 determines whether the processing of sorting the slot information in the pick order is necessary (step St809). When it is determined that the processing of sorting the slot information in the pick order is not necessary (step St809: NO), the arithmetic device advances the processing to step St810. When it is determined that the processing of sorting the slot information in the pick order is necessary (step St809: YES), the arithmetic device 2 executes the processing of sorting the slot information in the pick order (step St64).

Next, the arithmetic device 2 determines whether processing of correcting the slot position is necessary in accordance with the reference point in the simulation model (step St810). When it is determined that the processing of correcting the slot position is not necessary (step St810: NO), the arithmetic device 2 advances the processing to step St811. When it is determined that the processing of correcting the slot position is necessary (step St810: YES), the arithmetic device 2 executes the processing of correcting the slot position (step St65).

Next, the arithmetic device 2 determines whether the processing of correcting the pick position is necessary (step St811). When the processing of correcting the slot position is executed, the arithmetic device 2 determines that the processing of correcting the pick position is also necessary. This is because the arithmetic device 2 performs the correction similar to the correction of the slot position on the pick position. When it is determined that the processing of correcting the pick position is not necessary (step St811: NO), the arithmetic device 2 ends this processing flow. When it is determined that the processing of correcting the slot position is necessary (step St811: YES), the arithmetic device 2 executes the processing of correcting the pick position (step St66). Then, the arithmetic device 2 ends this processing flow.

As described above, the arithmetic device 2 may determine, based on the designated simulation target warehouse, whether the data conversion processing for the slot information of the simulation target warehouse is necessary. When it is determined that the data conversion processing is necessary, the arithmetic device 2 may generate the conversion slot information by performing the data conversion processing on the slot information. Then, the arithmetic device 2 may generate the simulation model based on the conversion slot information.

In the above embodiment, an example in which the 3D model of the warehouse is generated on the cyber space by visualizing the simulation model has been described. However, the present disclosure is not limited thereto, and the arithmetic device 2 may generate the 3D model of the warehouse on the cyber space regardless of the generation of the simulation model. In this case, for example, the arithmetic device 2 may generate the 3D model of the warehouse based on the wall information excluding the conversion slot position, the conversion slot size, the region information, and the wall ID.

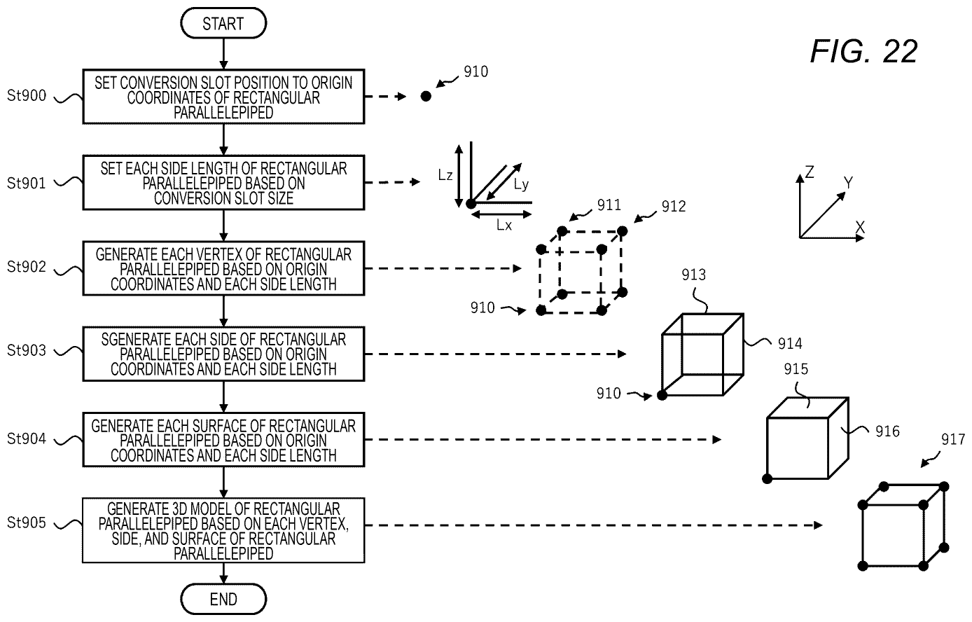

Generation of the 3D model of the warehouse will be described with reference to FIG. 22. FIG. 22 is a flowchart of 3D model generation processing according to the modification of Embodiment 1. When generating the 3D model of the warehouse, the arithmetic device 2 generates one or more rectangular parallelepipeds corresponding to the slot, each region, and walls of the warehouse. In the flowchart of FIG. 22, processing in which the arithmetic device 2 generates the rectangular parallelepiped corresponding to the slot will be described.

The arithmetic device 2 sets the conversion slot position of a certain slot to origin coordinates of the rectangular parallelepiped to be generated in the cyber space (step St900). Accordingly, in the example of FIG. 22, an origin 910 of the rectangular parallelepiped is set.

The arithmetic device 2 sets each side length of the rectangular parallelepiped to be generated based on the conversion slot size of the slot in which the conversion slot position is set to the origin coordinates of the rectangular parallelepiped in step St900 (step St901). Accordingly, the side length in the X axis direction of the generated rectangular parallelepiped is set to Lx, the side length in the Y axis direction is set to Ly, and the side length in the Z axis direction is set to Lz by the arithmetic device 2.

The arithmetic device 2 generates each vertex of the rectangular parallelepiped based on the origin coordinates set in step St900 and the side lengths set in step St901 (step St902). Accordingly, each vertex (for example, a vertex 911 and a vertex 912) of the generate rectangular parallelepiped is generated.

The arithmetic device 2 generates each side of the rectangular parallelepiped based on the origin coordinates set in step St900 and each side length set in step St901 (step St903). Accordingly, each side (for example, a side 913 and a side 914) of the generated rectangular parallelepiped is generated.

The arithmetic device 2 generates each surface of the rectangular parallelepiped based on the origin coordinates set in step St900 and the side lengths set in step St901 (step St904). Accordingly, each surface (for example, a surface 915 and a surface 916) of the generated rectangular parallelepiped is generated.

The arithmetic device 2 generates a 3D model of the rectangular parallelepiped based on each vertex, side, and surface of the rectangular parallelepiped generated in steps St902, St903, and St904, respectively (step St905). Accordingly, a rectangular parallelepiped 917 is generated in the cyber space. The rectangular parallelepiped 917 corresponds to one of the slots in the actual warehouse.

As described above, the arithmetic device 2 can reproduce the rectangular parallelepiped corresponding to each of the slots in the actual warehouse in the cyber space as the 3D model. The arithmetic device 2 can generate one or more rectangular parallelepipeds corresponding to the slot based on the data of the position and size of the slot in the cyber space provided in the conversion slot information, that is, the conversion slot position and the conversion slot size.

Although not illustrated in FIG. 22, the arithmetic device 2 can similarly generate the 3D model of each region and the walls of the warehouse. The arithmetic device 2 can generate one or more rectangular parallelepipeds corresponding to each region based on the start point and end point positions of each region of the warehouse provided in the region information. For example, the start point of the region may be set as the origin, and each vertex, side, and surface may be generated based on the coordinates of the start point and the end point. When each region is defined as a plane, the length of each side of the rectangular parallelepiped in the Z axis direction may be set to 0. Further, the arithmetic device 2 can generate one or more rectangular parallelepipeds corresponding to the walls based on the data of the start point and end point positions and the heights of the walls provided in the wall information. For example, the height of the wall may be set as the length of the side of the rectangular parallelepiped corresponding to the wall in the Z axis direction. The arithmetic device 2 may set the color of the generated rectangular parallelepiped based on the visibility of the walls.

As described above, the arithmetic device 2 can generate the 3D model of the warehouse by generating one or more rectangular parallelepipeds corresponding to each of the slot of the warehouse, the predetermined region present in the warehouse, and the walls of the warehouse in the cyber space.

Accordingly, for example, the layout of the warehouse can be examined with a lower processing load than the automatic generation of the simulation model.

The idea of the above embodiment may be applied to a factory, a retail store, and the like.

### Summary of Embodiment 1

The following techniques are disclosed by the above description of Embodiment 1.

### Technique A1

A simulation model generation method is executed by an arithmetic device, the arithmetic device being connected to a warehouse management system that manages a stock state of articles stored in each of a plurality of warehouses so as to be able to perform data communication, and includes: receiving designation of a simulation target warehouse by a user operation; acquiring, from the warehouse management system, slot information including a position and a size of a slot in which the articles stored in the simulation target warehouse are stored according to the designation; and generating a simulation model for managing work in the simulation target warehouse based on the slot information.

Accordingly, the arithmetic device can automatically generate the simulation model for managing the warehouse work according to the simulation target warehouse, and improve the convenience of the warehouse work.

### Technique A2

In the simulation model generation method according to Technique A1, the arithmetic device may generate conversion slot information by performing, on the slot information, data conversion processing for standardizing slot information that is used identically or differently for each warehouse managed by the warehouse management system, and may generate the simulation model based on the conversion slot information.

Accordingly, the arithmetic device can commonize the slot information even when the slot information is different for each warehouse management system or each warehouse.

### Technique A3

In the simulation model generation method according to Technique A1 or A2, the arithmetic device may generate passage information of a passage present in the simulation target warehouse based on the conversion slot information.

Accordingly, the arithmetic device can generate the passage present in the simulation target warehouse as a part of the simulation model.

### Technique A4

In the simulation model generation method according to Technique A3, the arithmetic device may generate region information of at least one predetermined region present in the simulation target warehouse based on the conversion slot information and the passage information.

Accordingly, the arithmetic device can generate at least one predetermined region present in the simulation target warehouse as a part of the simulation model.

### Technique A5

In the simulation model generation method according to Technique A4, the arithmetic device may generate wall information of a wall present in the simulation target warehouse based on the region information.

Accordingly, the arithmetic device can generate the wall present in the simulation target warehouse as a part of the simulation model.

### Technique A6

In the simulation model generation method according to Technique A5, the arithmetic device may generate a layout of the simulation target warehouse based on the conversion slot information, the passage information, the region information, and the wall information.

Accordingly, the arithmetic device can generate the layout of the simulation target warehouse as a part of the simulation model.

### Technique A7

In the simulation model generation method according to any one of Techniques A1 to A6, the arithmetic device may generate a pick list that is an execution condition of the simulation using an identifier of the slot.

Accordingly, the arithmetic device can examine the optimization of the warehouse work by executing the simulation.

### Technique A8

In the simulation model generation method according to Technique A7, the arithmetic device may generate stock information of the articles stored in the slot based on the pick list.

Accordingly, the arithmetic device can prevent, for example, occurrence of an error in the stock status.

### Technique A9

A program causing an arithmetic device, the arithmetic device being connected to a warehouse management system that manages stock information of articles stored in each of a plurality of warehouses so as to be able to perform data communication, to execute processing of: receiving designation of a simulation target warehouse by a user operation; acquiring, from the warehouse management system, slot information including a position and a size of a slot in which the articles stored in the simulation target warehouse are stored according to the designation; and generating a simulation model for managing work in the simulation target warehouse based on the slot information.

Accordingly, the arithmetic device can automatically generate the simulation model for managing the warehouse work according to the simulation target warehouse, and improve the convenience of the warehouse work.

### Technique A10

In a simulation model generation system including an arithmetic device, the arithmetic device being connected to a warehouse management system that manages a stock state of articles stored in each of a plurality of warehouses so as to be able to perform data communication, the arithmetic device receives designation of a simulation target warehouse by a user operation; acquires, from the warehouse management system, slot information including a position and a size of a slot in which the articles stored in the simulation target warehouse are stored according to the designation; and generates a simulation model for managing work in the simulation target warehouse based on the slot information.

Accordingly, the arithmetic device can automatically generate the simulation model for managing the warehouse work according to the simulation target warehouse, and improve the convenience of the warehouse work.

### Technique B1

A simulation model generation method executed by an arithmetic device, the arithmetic device being connected to a management system that manages a stock state of articles so as to be able to perform data communication, includes: acquiring, from the management system, slot information including a position of a slot in which the articles are stored; and generating a simulation model based on the slot information.

Accordingly, the arithmetic device can generate the simulation model based on the slot information including the position of the slot in which the articles are stored.

### Technique B2

In the simulation model generation method according to Technique B1, the management system may manage the stock state of the articles stored in each of a plurality of warehouses, the arithmetic device may receive designation of a simulation target warehouse by a user operation, and may acquire, from the management system, slot information for storing articles stored in the simulation target warehouse according to the designation.

Accordingly, the arithmetic device can automatically generate the simulation model according to the simulation target warehouse. Accordingly, for example, it is possible to improve convenience of a warehouse work.

### Technique B3

In the simulation model generation method according to Technique B2, the arithmetic device may generate conversion slot information by performing, on the slot information, data conversion processing for standardizing slot information that is used identically or differently for each management system or each warehouse, and may generate the simulation model based on the conversion slot information.

Accordingly, the arithmetic device can commonize the slot information even when the slot information is different for each management system or each warehouse.

### Technique B4

In the simulation model generation method according to Technique B3, the arithmetic device may determine, based on the simulation target warehouse designated by the user operation, whether the data conversion processing is necessary for slot information of the simulation target warehouse, generate, in response to determining that the data conversion processing is necessary, the conversion slot information by performing the data conversion processing on the slot information, and generate the simulation model based on the conversion slot information.

Accordingly, the arithmetic device can execute the data conversion processing after determining the necessity of the data conversion processing on the slot information. Accordingly, the arithmetic device can reduce a load when generating the simulation model.

### Technique B5

In the simulation model generation method according to Technique B4, the arithmetic device may generate passage information of a passage present in the simulation target warehouse based on the conversion slot information.

Accordingly, the arithmetic device can generate the passage present in the simulation target warehouse as a part of the simulation model.

### Technique B6

In the simulation model generation method according to Technique B5, the arithmetic device may generate region information of at least one predetermined region present in the simulation target warehouse based on the conversion slot information and the passage information.

Accordingly, the arithmetic device can generate at least one predetermined region present in the simulation target warehouse as a part of the simulation model.

### Technique B7

In the simulation model generation method according to Technique B6, the arithmetic device may generate wall information of a wall present in the simulation target warehouse based on the region information.

Accordingly, the arithmetic device can generate the wall present in the simulation target warehouse as a part of the simulation model.

### Technique B8

In the simulation model generation method according to Technique B7, the arithmetic device may generate a 3D model of the simulation target warehouse based on the conversion slot information, the region information, and the wall information.

Accordingly, the arithmetic device can generate the 3D model of the warehouse separately from the simulation model. Accordingly, for example, when only the 3D model of the warehouse is required, the arithmetic device can reproduce the warehouse in a cyber space with a lower load than when generating the simulation model.

### Technique B9

In the simulation model generation method according to Technique B8, the conversion slot information may include data of a position and a size of the slot in a cyber space, the region information may include data of a position of the predetermined region in the cyber space, the wall information may include data of a position and a height of the wall in the cyber space, and the arithmetic device may generate the 3D model by generating one or more rectangular parallelepipeds corresponding to each of the slot, the predetermined region, and the wall in the cyber space based on the data.

Accordingly, the arithmetic device can generate the 3D model by generating the one or more rectangular parallelepipeds corresponding to each of the slot, the region, and the wall of the warehouse in the cyber space.

### Technique B10

A program causes an arithmetic device, the arithmetic device being connected to a management system that manages stock information of articles so as to be able to perform data communication, to execute processing of: acquiring, from the management system, slot information including a position of a slot in which the articles are stored; and generating a simulation model based on the slot information.

Accordingly, the program can obtain effects similar to those of the technique B1.

### Technique B11

In a simulation model generation system including an arithmetic device, the arithmetic device being connected to a management system that manages a stock state of articles so as to be able to perform data communication, the arithmetic device acquires slot information including a position of a slot in which the articles are stored from the management system, and generates a simulation model based on the slot information.

Accordingly, the simulation model generation system can obtain effects similar to those of Technique B1.

### Embodiment 2

In Embodiment 1, an example in which the arithmetic device 2 generates the simulation model related to the warehouse work based on the warehouse information acquired from the warehouse management system has been described. In Embodiment 2, a method of generating a model for simulating movement of articles based on information acquired from a management system that manages stock information of the articles will be described. In Embodiment 2, a transport management system as a management system will be described by taking transport and delivery of the articles as an example of the movement of the articles. In the description of Embodiment 2, the same content as the description of Embodiment 1 may be simplified or omitted.

### System Configuration

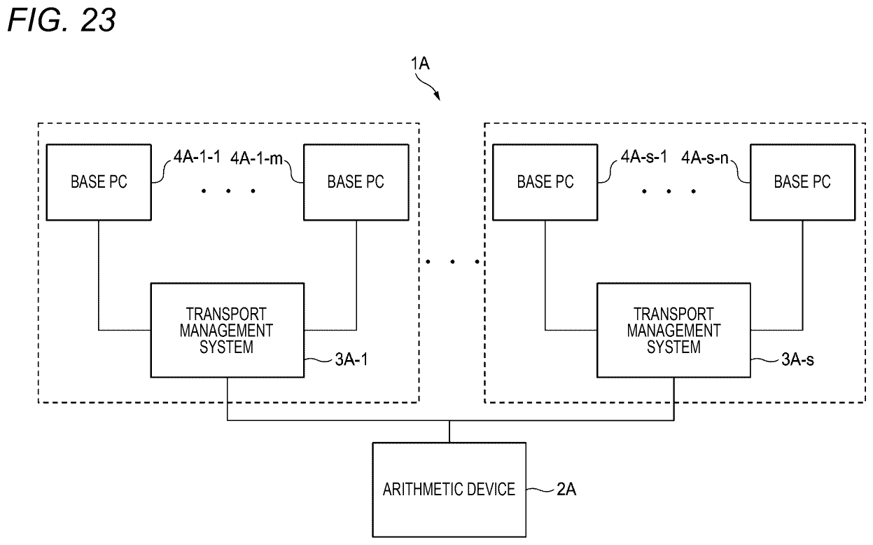

FIG. 23 is a block diagram illustrating a configuration example of a simulation model generation system 1A according to Embodiment 2. The simulation model generation system 1A includes an arithmetic device 2A and at least one transport management system 3A-1, . . . , or 3A-s (s being an integer of 2 or more). The simulation model generation system 1A is a system in which the arithmetic device 2A automatically generates a simulation model for managing physical distribution work based on information on each base stored in the transport management systems 3A-1 to 3A-s, thereby supporting study of optimization of the physical distribution work. In Embodiment 2, the base means a place where an article is stored. Specific examples of the base include various bases in a supply chain such as a warehouse, a factory, a retail store, a physical distribution center, a customer base, a parking lot in a container yard, or a parking lot in a truck yard. The customer base is, for example, a facility of a customer of a user who uses the transport management systems.

The arithmetic device 2A is implemented using a general-purpose computer device (for example, a personal computer or a server computer). The arithmetic device 2A is connected to one or a plurality of transport management systems so as to be able to input and output data. The arithmetic device 2A may be connectable to a user terminal (for example, a PC) (not illustrated).

The transport management system 3A-1 is a system for managing a stock status of articles managed at a base, loading and unloading of the articles at the base, and the like. The transport management system 3A-1 may be referred to as a transport management system (TMS). Further, the transport management system 3A-1 may be capable of managing one or a plurality of bases, and may be connectable to base PCs 4A-1-1, . . . , 4A-1-m (m being an integer of 2 or more) for management of the bases. The other transport management systems are similar to the transport management system 3A-1. For example, the transport management system 3A-s may be connectable to base PCs 4A-s-1, . . . , 4A-s-n (n being an integer of 2 or more).

The base PC 4A-1-1 is installed, for example, in a base (not illustrated) to record the stock status of articles managed at the base, and the like. The base PC 4A-1-1 may record the stock status and the like in real time by, for example, receiving various types of data from a terminal such as a handy terminal. Further, the base PC 4A-1-1 is connectable to the transport management system 3A-1, and can transmit the stock status of articles managed at the base, and the like, to the transport management system 3A-1. The other base PCs are similar to the base PC 4A-1-1. For example, the base PC 4A-s-1 may be connectable to the transport management system 3A-s. Further, the base PCs 4A-1-1 to 4A-1-m and the base PCs 4A-s-1 to 4A-s-n may be installed in different bases. In the following description, the transport management system 3A-1 and the base PC 4A-1-1 are used when the transport management system and the base PC need to be described individually, and reference numerals are omitted when they are collectively described.

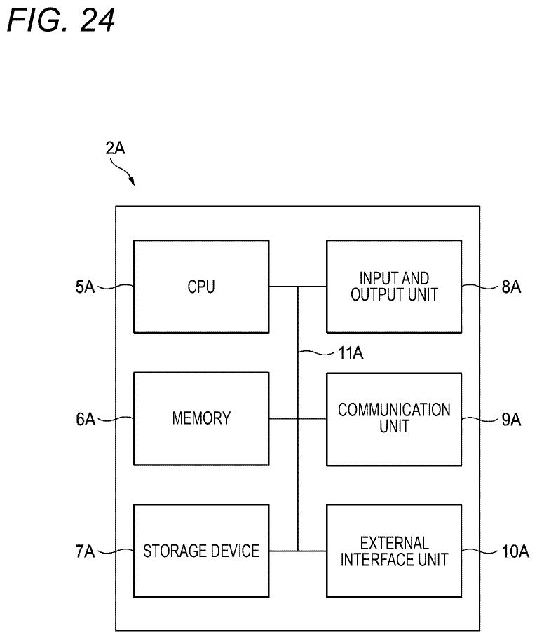

FIG. 24 is a block diagram illustrating a configuration example of the arithmetic device 2A according to Embodiment 2. The arithmetic device 2A includes a CPU 5A, a memory 6A, a storage device 7A, an input and output unit 8A, a communication unit 9A, and an external interface unit 10A. Each unit provided in the arithmetic device 2A is communicably connected by an internal bus 11A.

Since the CPU 5A, the memory 6A, the storage device 7A, the input and output unit 8A, the communication unit 9A, and the external interface unit 10A provided in the arithmetic device 2A have the same configuration as the CPU 5, the memory 6, the storage device 7, the input and output unit 8, the communication unit 9, and the external interface unit 10 provided in the arithmetic device 2, respectively, description thereof will be omitted. The transport management system may also be implemented by a hardware configuration similar to that of the arithmetic device 2A.

### Processing Sequence

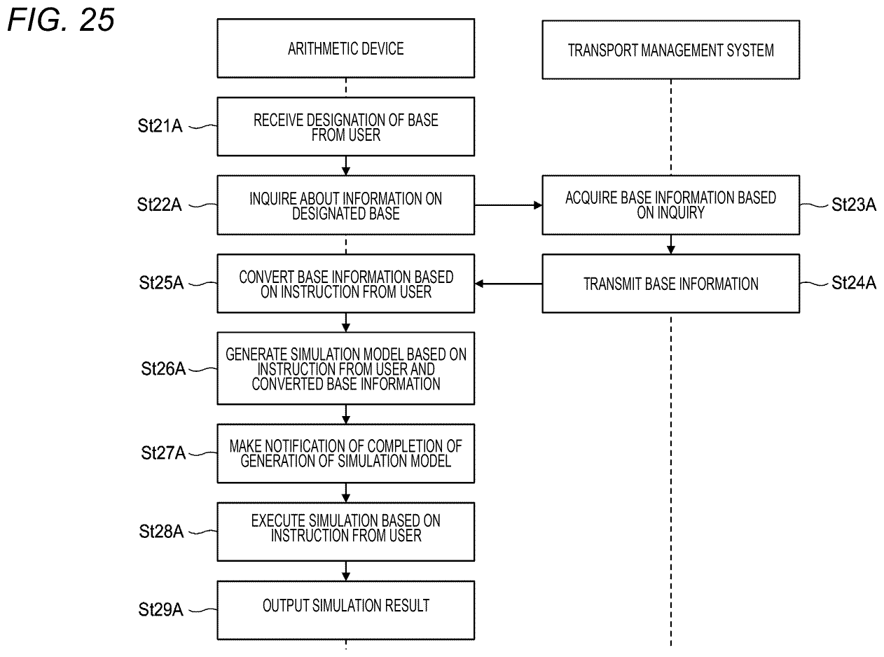

A processing sequence of the simulation model generation system 1A according to Embodiment 2 will be described with reference to FIG. 25. FIG. 25 is a sequence diagram of processing of the simulation model generation system 1A according to Embodiment 2. Processing in each processing sequence is performed in cooperation with the arithmetic device 2A and the transport management system. However, some processing of the sequence may be executed based on a user operation.

The arithmetic device 2A receives an input designating a simulation target base by the user (step St21A). The input content may be, for example, an identification number such as a name, a location, or an ID of a simulation target base. The input may be performed directly on the arithmetic device 2A or may be performed from the user terminal (not illustrated) or the like. Here, description will be given assuming that the user designates two or more simulation target bases. This is because the simulation model generation system 1A requires two or more bases in the simulation in order to implement the simulation of physical distribution. Alternatively, the arithmetic device 2A may receive designation of a specific country, region, or customer by the user. In this case, the base provided in the designated country or region, or the base of the designated customer is designated as the simulation target.

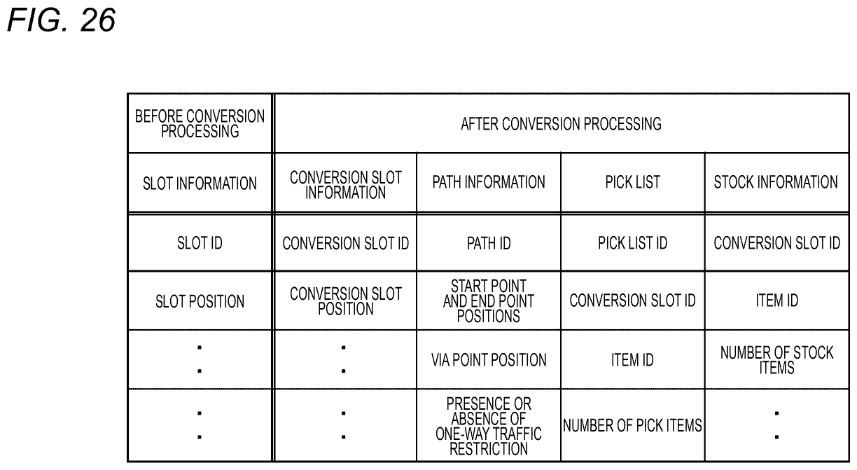

Based on the input in step St21A, the arithmetic device 2 inquires of one or more transport management systems about the simulation target base (step St22A). The content of the inquiry is to request information necessary for automatic generation of the simulation model. The information will be described later with reference to FIG. 26.

The transport management system acquires information on the one or the plurality of simulation target bases stored in the transport management system in response to the inquiry from the arithmetic device 2A (step St23A). A method through which the transport management system acquires the information is not particularly limited. For example, when the transport management system acquires the information, the transport management system may retrieve the information by searching a storage device or the like of the transport management system. Further, when necessary information is not found, the transport management system may acquire the information by making an inquiry to the base PC of each of the one or the plurality of simulation target bases. Hereinafter, the base information acquired by the transport management system may be referred to as “slot information”.

The transport management system transmits the slot information acquired in step St23A to the arithmetic device 2A (step St24A).

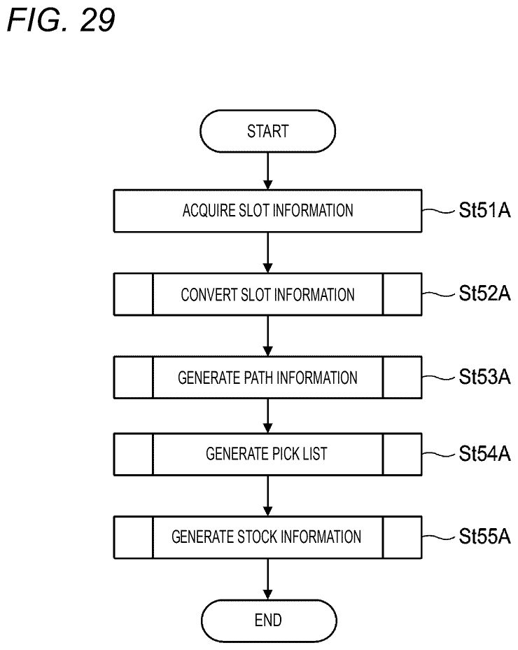

When there is an instruction from the user, the arithmetic device 2A executes data conversion processing on the slot information acquired from each of the one or more transport management systems in step St24A (step St25A). The instruction of the user may be directly input to the arithmetic device 2A or may be performed from the user terminal (not illustrated) or the like. This similarly applies to the processing of the following steps St26A and St28A. Hereinafter, converted information obtained by the data conversion processing may be referred to as “converted information”. The converted information will be described later with reference to FIG. 26. Details of the data conversion processing will be described later with reference to FIGS. 29 to 33.

When there is the instruction from the user, the arithmetic device 2A automatically generates the simulation model for virtually managing the physical distribution work at the plurality of simulation target bases based on the converted information obtained by the conversion processing of step St25A (step St26A). The simulation model is generated in, for example, a cyber space.

When the generation of the simulation model is completed, the arithmetic device 2A notifies the user of the completion (step St27A). The arithmetic device 2A may notify the user by the input and output unit 8A such as a display (not illustrated).

When there is the instruction from the user, the arithmetic device 2A executes a simulation based on the generated simulation model (step St28A).

When the executed simulation ends, the arithmetic device 2A outputs a simulation result (step St29A). The arithmetic device 2A may display the simulation result on, for example, the display (not illustrated). The arithmetic device 2A may output the simulation result as, for example, a text file.

### Slot Information

FIG. 26 is a table diagram illustrating data before and after conversion processing by the arithmetic device 2A according to Embodiment 2. In the present embodiment, a slot is a place where articles are stored, and is synonymous with a base.

The slot information includes a slot ID and a slot position as data. The slot ID is an identifier of the slot, and a different slot ID is assigned to each slot. The slot position indicates the position of the base, and is represented using, for example, latitude and longitude.

In the present embodiment, description will be given assuming that the slot information includes the slot ID and the slot position. However, the data configuration, the data name, and the like of the slot information may be different for each transport management system. For example, even if the same type of information is stored in the transport management system 3A-1 and the transport management system 3A-s, the data configuration and the data name of the information stored in both systems may be different. Since the transport management system is provided by various companies and the like, the format of data may be different for each transport management system. Similarly, the data configuration of the slot information of the base managed by the base PC may be different for each base PC as a target to be managed by the same transport management system. Therefore, the data configuration and the data name of the slot information transmitted from the transport management system to the arithmetic device 2A are not intended to be limited to the slot ID and the slot position, and data corresponding thereto may be included.

The converted information obtained by the data conversion processing executed in the processing of step St25A of FIG. 25 includes conversion slot information, path information, a pick list, and stock information. The slot information transmitted from the transport management system to the arithmetic device 2A may have a different data configuration for each transport management system or each base PC. Therefore, when automatically generating the simulation model, the arithmetic device 2A uses the data conversion processing to generalize (in other words, commonize) the information. Accordingly, it is possible to automatically generate the simulation model based on the generalized information from information acquired from any transport management system of the transport management systems 3A to 1-3A-s.

The conversion slot information includes a conversion slot ID and a conversion slot position as data. The conversion slot ID is a slot ID subjected to anonymization processing. The anonymization processing is processing of preventing information on a customer or the like from being acquired from the slot ID. An example of the conversion slot ID is an integer value such as “00001”. The conversion slot position is a slot position that has been corrected for the automatic generation of the simulation model.

The path information includes a path ID, start point and end point positions, a via point position, and the presence or absence of one-way traffic restriction as data. In the simulation, a truck or the like moves along a path between bases. The path ID is an identifier of the path. The start point and end point positions indicates a start point and an end point of the path, and is represented, for example, by coordinates of latitude and longitude. The via point position indicates a point through which a truck or the like passes in the simulation, and is represented, for example, by coordinates of latitude and longitude. The presence or absence of the one-way traffic restriction indicates whether the path is one-way traffic.

The pick list includes a pick list ID, a conversion slot ID, an item ID, and the number of pick items as data. Here, the item refers to an article stored in a slot. The pick list includes information indicating which article is picked from which base (slot). The pick list ID is an identifier of the pick list. The item ID is an identifier of the article. The number of pick items indicates the number of articles to be picked.

The stock information includes a conversion slot ID, an item ID, and the number of stock items as data. The number of stock items indicates the stock quantity of articles stored in the slot before the execution of the simulation.

### Example of Simulation Model

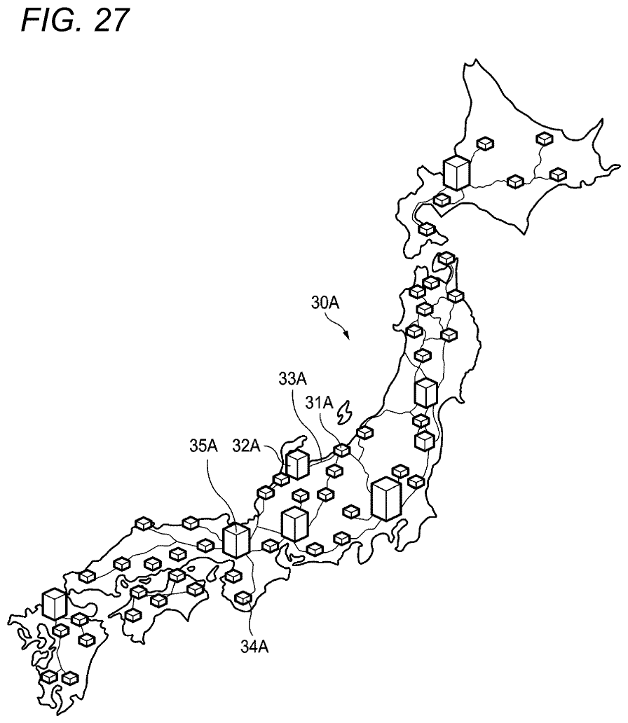

FIG. 27 illustrates a simulation model 30A generated in the cyber space based on the converted information. FIG. 27 is a schematic diagram illustrating the simulation model 30A according to Embodiment 2. In the simulation model 30A, the simulation target bases are visualized. In the example of FIG. 27, each base is visualized in the simulation model 30A. The simulation model 30A illustrated in FIG. 27 is an example, and is not intended to limit a target region of the simulation, the number of bases, and the like.

For example, in the simulation using the simulation model 30A, physical distribution between a base 31A and a base 32A may be executed. A truck or the like that transports an article between the base 31A and the base 32A moves, for example, along a path 33A connecting the base 31A to the base 32A. Further, for example, when the physical distribution between the base 31A and a base 34A is simulated, a base 35A may be set as a via point.

Each base in the simulation model 30A is generated based on the conversion slot information. Further, each path in the simulation model 30A is generated based on the path information. The country or region including each base and path may or may not be visualized. The arithmetic device 2A may store and hold information for visualizing each country or a region in each country, and information for generating the path information in advance. The information for generating the path information may be, for example, geography and road information of a specific region.

In the example of FIG. 27, the slot is visualized as a rectangular parallelepiped, but is not limited thereto. For example, the slot may be visualized so that the type of the slot (for example, factory, warehouse, or the like) can be distinguished.

### Processing of Transport Management System

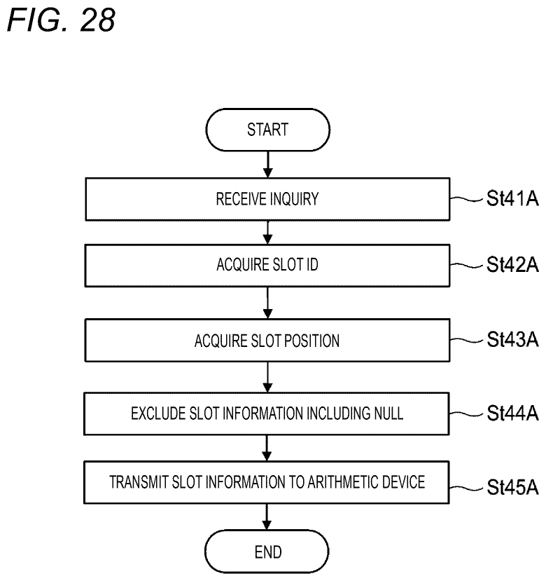

A flow of processing of the transport management system according to Embodiment 2 will be described with reference to FIG. 28. FIG. 28 is a flowchart of processing of the transport management system according to Embodiment 2. The transport management system receives an inquiry about a simulation target slot (base) from the arithmetic device 2A (step St41A).

The transport management system acquires the slot ID for the simulation target slot (step St42A). The slot ID may be assigned to the slot by the transport management system.

The transport management system acquires the slot position for the simulation target slot (step St43A).

The transport management system excludes slot information including NULL in the data (step St44A). The data being NULL indicates a state in which the data does not contain a value. Here, the exclusion refers to preventing transmission to the arithmetic device 2A. When the data of the slot ID or the slot position of any slot is NULL, the slot information of the slot is excluded.

The transport management system transmits the slot information of the simulation target slot to the arithmetic device 2 (step St45A). Then, this processing flow ends.

### Data Conversion Processing

A flow of the data conversion processing executed by the arithmetic device 2A according to Embodiment 2 will be described with reference to FIG. 29. FIG. 29 is a flowchart of the data conversion processing according to Embodiment 2. At the start time of the processing flow illustrated in FIG. 29, the processing of step St45A of the transport management system illustrated in FIG. 28 is completed. The arithmetic device 2A acquires the slot information transmitted from the transport management system (step St51A). The arithmetic device 2A may acquire the slot information of each of the plurality of slots in step St51A. For example, a case is conceivable in which the arithmetic device 2A acquires one piece of slot information transmitted from the transport management system 3A-1, one piece of slot information transmitted from the transport management system 3A-2, and two pieces of slot information transmitted from the transport management system 3A-3.

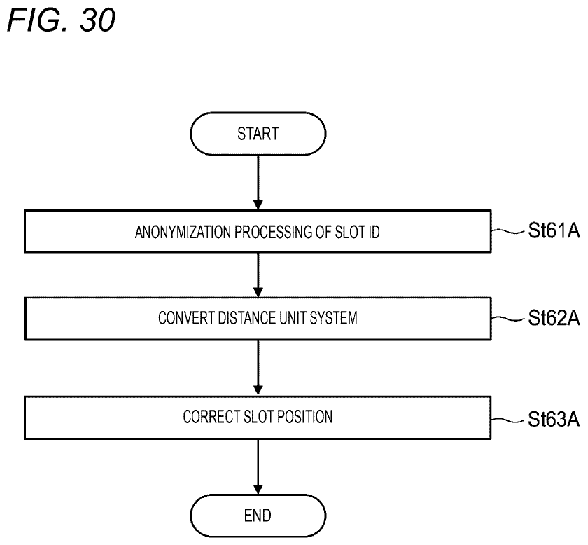

The arithmetic device 2A converts the slot information acquired in step St51A and generates the conversion slot information (step St52A). Details of this step will be described later with reference to FIG. 30.

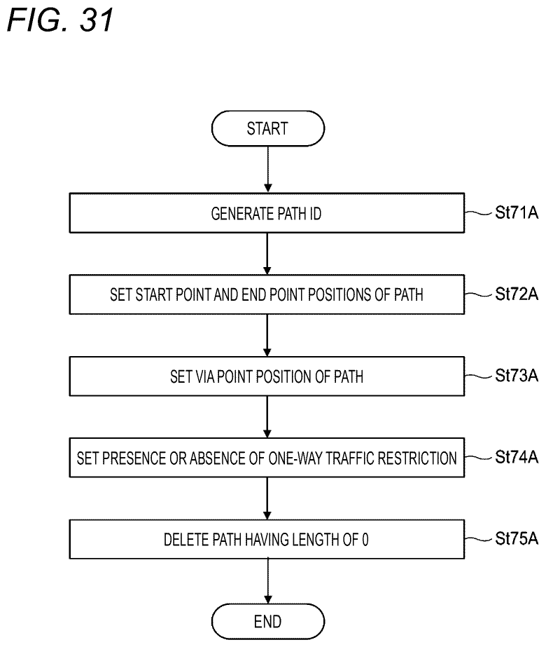

The arithmetic device 2A generates path information between simulation target slots based on the conversion slot information generated in step St52A (step St53A). Details of this step will be described later with reference to FIG. 31.

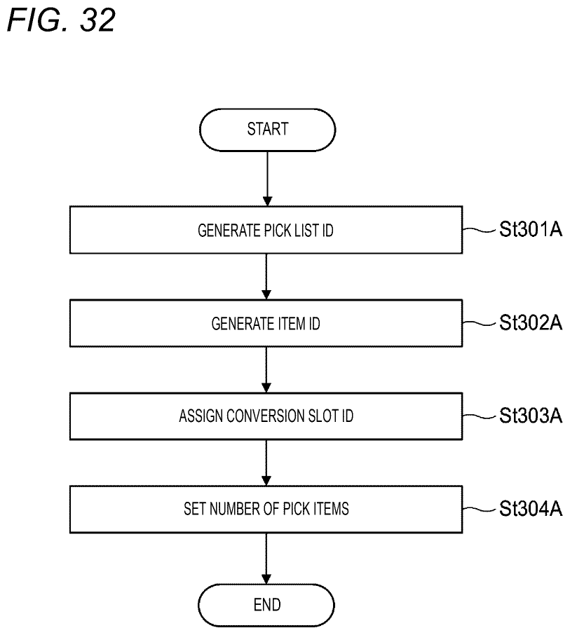

The arithmetic device 2A generates a pick list including one or more slots based on the conversion slot information generated in step St52A (step St54A). Details of this step will be described later with reference to FIG. 32.

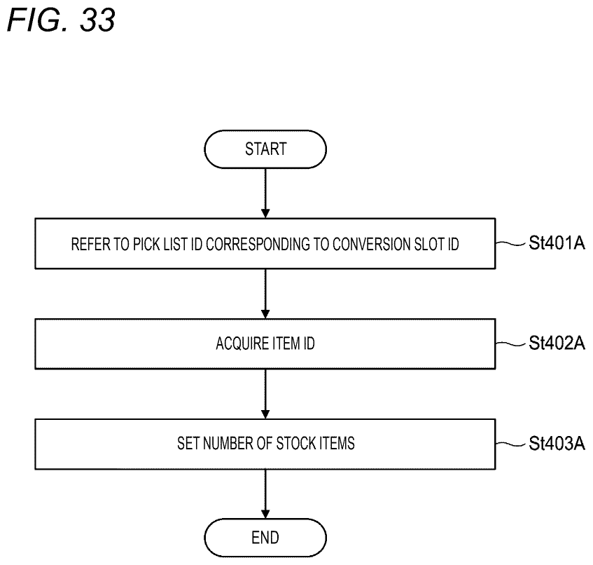

Based on the pick list generated in step St54A, arithmetic device 2A generates stock information of the articles stored in the slot provided in the pick list (step St55A). Details of this step will be described later with reference to FIG. 33. After the processing of step St55A, the arithmetic device 2A ends this processing flow.

### Slot Information Conversion

A flow of slot information conversion processing executed by the arithmetic device 2A according to Embodiment 2 will be described with reference to FIG. 30. FIG. 30 is a flowchart of slot information conversion processing according to Embodiment 2. At a start time of the processing flow illustrated in FIG. 30, the arithmetic device 2A has acquired the slot information transmitted from the transport management system.

The arithmetic device 2A executes the anonymization processing of the slot ID among the slot information acquired in step St51A (step St61A). By the anonymization processing, the slot ID becomes the conversion slot ID. The slot ID may be converted such that integer values such as “00001”, “00002”, and “00003” are consecutive numbers.

The arithmetic device 2A converts data including a unit of distance in the slot information acquired in step St51A into a distance unit system used in the simulation model (for example, the simulation model 30A) (step St62A).

The arithmetic device 2A corrects the slot position in accordance with a reference point in the simulation model (step St63A). For example, when the arithmetic device 2A generates the simulation model in a two-dimensional orthogonal coordinate system including the X axis and the Y axis, an origin of the two-dimensional orthogonal coordinate system may be used as the reference point. In this case, the arithmetic device 2A corrects all the slot positions of the simulation target slots such that a slot position of a slot having the smallest distance from the origin among the simulation target slots is positioned at the origin. For example, when the slot position of the slot having a smallest distance from the origin has an X coordinate of 100 and a Y coordinate of 200, the X coordinate and the Y coordinate of all the slot positions of the simulation target slots are corrected to −100 and −200, respectively. Thus, the slot position becomes the conversion slot position.

When the processing of step St62A and step St63A is unnecessary, the arithmetic device 2A may omit the processing. For example, when the slot information does not include data including the unit of distance, or when the slot information includes the data including the unit of distance, and the unit is the similar to the unit of distance used in the simulation model, the processing of step St62A may be omitted. When the slot position is represented using the coordinates of latitude and longitude, the processing of step St63A may be omitted.

Through the processing from step St61A to step St63A, the arithmetic device 2A generates the conversion slot information including the conversion slot ID and the conversion slot position. The conversion slot information may be generated as, for example, a CSV file. The CSV file may include data for each slot (for each conversion slot ID). The arithmetic device 2A generates information necessary for the automatic generation of the simulation model and the execution of the simulation based on the conversion slot information.

### Generation of Path Information

Path information generation processing executed by the arithmetic device 2A according to Embodiment 2 will be described with reference to FIG. 31. FIG. 31 is a flowchart of the path information generation processing according to Embodiment 2.

The arithmetic device 2A generates the path ID (step St71A). The path ID may be a consecutive integer value such as “00001”, “00002”, and “00003”.

The arithmetic device 2A sets the start point and end point positions of the path based on the conversion slot position of each of two or more slots (step St72A). The arithmetic device 2A sets the start point and end point positions of the path by combining a specific slot among the two or more slots and a slot different from the specific slot. This is because by determining a slot from which a truck or the like departs, in other words, a slot in which an article to be picked is stored, and a slot at which a truck or the like arrives, in other words, a slot to which the article is transported, the start point and end point positions of the path are automatically determined. For example, the arithmetic device 2A may receive a setting by an administrator or the like of the simulation model generation system 1A such that a truck departing from the specific slot in the simulation moves along a specific path. A plurality of paths may be generated by setting the start point and end point positions. This is because there may be a plurality of ways to get from the start point to the end point.

The arithmetic device 2A sets each via point position of the path for which the start point and end point positions are set in step St72A (step St73A). The via point may be, for example, a point through which the truck or the like always passes based on the positions of the start point and the end point, or the via point may be set to satisfy conditions set in advance by the user regarding the via point. Examples of the conditions related to the via point include a condition that a truck or the like can move from a start point to an end point in a time as short as possible, and a condition that the specific slot is set as the via point when the truck or the like moves in a specific region.

The arithmetic device 2A sets the presence or absence of the one-way traffic restriction of the path for each path generated by executing the processing of steps St71A to St73A (step St74A). In the path in which the one-way traffic restriction is set, the path is one-way traffic from the start point to the end point.

The arithmetic device 2A deletes a path having a length of 0 among all the paths generated by executing the processing of step St71A to step St74A (step St75A). Here, the length refers to a distance between the start point and the end point. When the processing of step St75A is completed, the arithmetic device 2A ends this processing flow.

The path information may be generated as, for example, a CSV file. The CSV file may include data for each path (for each path ID).

### Generation of Pick List

FIG. 32 is a flowchart of pick list generation processing according to Embodiment 2. The pick list is minimum information necessary for executing the simulation using the generated simulation model.

The arithmetic device 2A generates the pick list ID (step St301A). The pick list ID may be a consecutive integer value such as “0001”, “0002”, and “0003”.

The arithmetic device 2A generates an item ID (step St302A). The item ID may be a consecutive integer value such as “0001”, “0002”, and “0003”. For example, the arithmetic device 2A associates the item ID “0002” with the pick list ID “0001”.

The arithmetic device 2A assigns a conversion slot ID to each pick list ID generated in step St301A (step St303A). Here, the conversion slot ID may be randomly allocated. By randomly allocating the conversion slot IDs, it is possible to examine optimization of the physical distribution work by executing the simulation. For example, the arithmetic device 2 assigns the conversion slot ID “00001” to the pick list ID “0001”. At this time, since the item ID “0002” is associated with the pick list ID “0001”, articles having the item ID “0002” are picked from the slot having the conversion slot ID “00001” when the simulation is executed. In the simulation, the truck or the like on which the picked articles are loaded moves on one of a plurality of paths with the slot having the conversion slot ID “00001” as a start point, and transports or delivers the articles to a slot different from the slot. At this time, the path may be randomly selected, or may be selected so as to satisfy conditions set by the user. Examples of the conditions set by the user include preferentially selecting a path with the slot having the conversion slot ID “00002” as the end point when the slot having the conversion slot ID “00001” is the start point, and selecting a specific path and transporting the articles having the item ID “0002” to the specific slot.

The arithmetic device 2 sets the number of pick items for each pick list ID generated in step St301A (step St304A). For example, the arithmetic device 2 sets the number of pick items to 10 corresponding to the pick list ID “0001”. When the processing of step St304A is completed, the arithmetic device 2 ends this processing flow.

A pick list is generated by the series of processing illustrated in FIG. 32. One pick list includes one pick list ID, one conversion slot ID, one item ID, and one number of pick items. For example, when the pick list ID, the conversion slot ID, the item ID, and the number of pick items provided in the pick list are “0001”, “00001”, “0002”, and “10”, respectively, the pick list means the following contents. That is, only 10 articles with the item ID “0002” stored in the slot with the conversion slot ID “00001” are picked based on the pick list with the pick list ID “0001”.

All the generated pick lists may be collected as, for example, a pick list file. The pick list file may be, for example, a CSV file.

### Generation of Stock Information

FIG. 33 is a flowchart of the stock information generation processing according to Embodiment 2. The arithmetic device 2A generates stock information based on the pick list generated by the series of processing illustrated in FIG. 32. According to this flow, the number of articles stored in the slot can be generated for each slot. In the description of this flow, stock information is generated based on the pick list with the pick list ID “0001” exemplified in the description of FIG. 32.

The arithmetic device 2A refers to the pick list ID corresponding to the conversion slot ID (step St401A). For example, the arithmetic device 2A refers to the pick list ID “0001” corresponding to the conversion slot ID “00001”. Accordingly, the arithmetic device 2A can acquire the item ID and the number of items provided in the pick list having the pick list ID of “0001”.

The arithmetic device 2A acquires the item ID corresponding to the pick list ID referred to in step St401A (step St402A). For example, the arithmetic device 2A acquires the item ID “0002” corresponding to the pick list ID “0001”. The arithmetic device 2A sets the acquired item ID as data of the stock information.

The arithmetic device 2A sets the number of stock items for each item ID acquired in step St402A (step St403A). For example, the arithmetic device 2A sets the number of stock items of the articles with the item ID “0002” to 10. When the simulation is executed according to the pick list having the pick list ID “0001” exemplified in the description of FIG. 32, the number of articles having the item ID “0002” stored in the slot having the conversion slot ID “00001” is as follows. That is, since the number of stock items before the execution of the simulation is 10 and only 10 items are picked in the simulation, the number of stock items after the execution of the simulation is completed is 0. The arithmetic device 2A may set the number of stock items so as to prevent an error from occurring due to stock shortage when the simulation is executed. For example, the number of stock items of a certain conversion slot ID may be set in advance by the user to be equal to or less than the number of pick items of the conversion slot ID. When the processing of step St403A is completed, the arithmetic device 2A ends this processing flow.

The stock information may be generated as, for example, a CSV file. The CSV file may include the stock quantity for each slot (for each conversion slot ID).

### Generation of Simulation Model and Simulation Execution

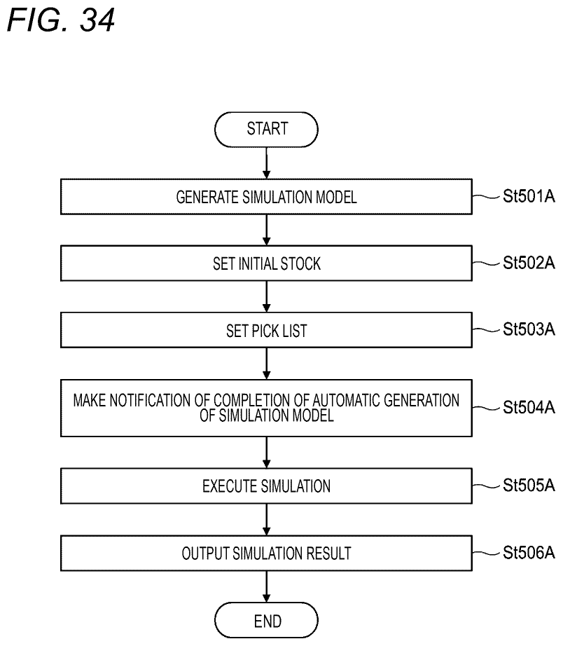

FIG. 34 is a flowchart of simulation model generation and simulation execution processing according to Embodiment 2. At a start time of this flow, the arithmetic device 2A has completed the series of processing illustrated in FIG. 29. That is, the data conversion processing is completed. The arithmetic device 2A receives an instruction to automatically generate the simulation model from the user.

The arithmetic device 2A generates the layout of the simulation model based on the conversion slot information and the path information (step St501A).

The arithmetic device 2A sets an initial stock of the articles stored in the slot based on the stock information (step St502A). Depending on the stock information of the slot, nothing may be stored in the slot. Depending on the stock information and the pick list, nothing may be stored in the slot after the execution of the simulation. The display mode of the slot generated in the cyber space may be set in advance so that the user can visually recognize that some article is stored in the slot. For example, the slot in which the article is stored and the slot in which the article is not stored may be displayed in different colors, or the stock quantity may be displayed in the slot.

The arithmetic device 2A sets one or more pick lists for the simulation (step St503A). Here, the arithmetic device 2A may set the simulation pick list by reading a pick list file in which a plurality of pick lists are collected.

When the automatic generation of the simulation model is completed, the arithmetic device 2A notifies the user of the completion (step St504A).

When receiving the instruction to execute the simulation from the user, the arithmetic device 2A executes the simulation (step St505A). During the execution of the simulation, for example, a state in which a truck or the like moves on the simulation model may be confirmed by the user.

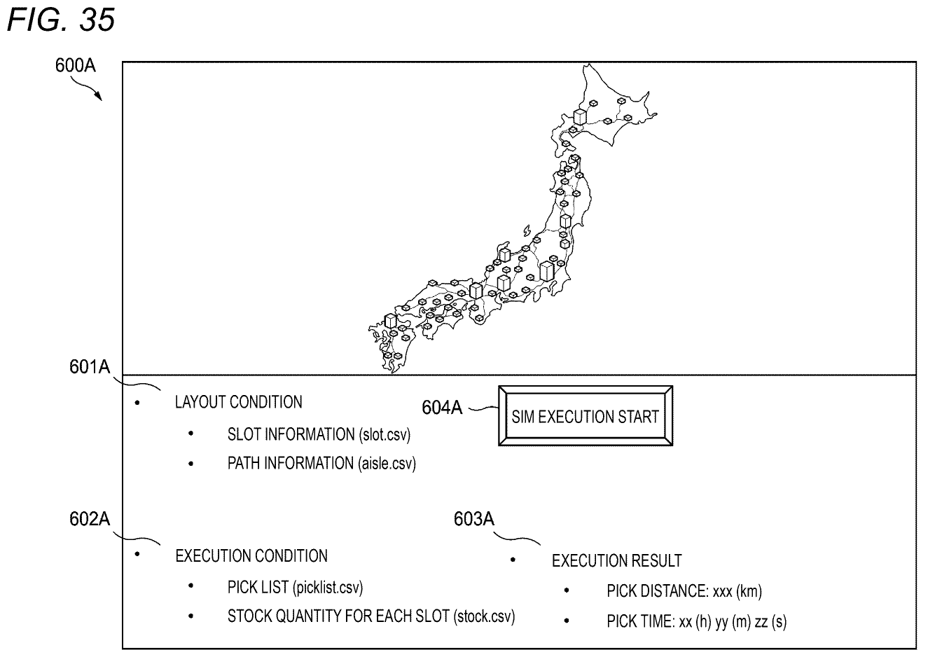

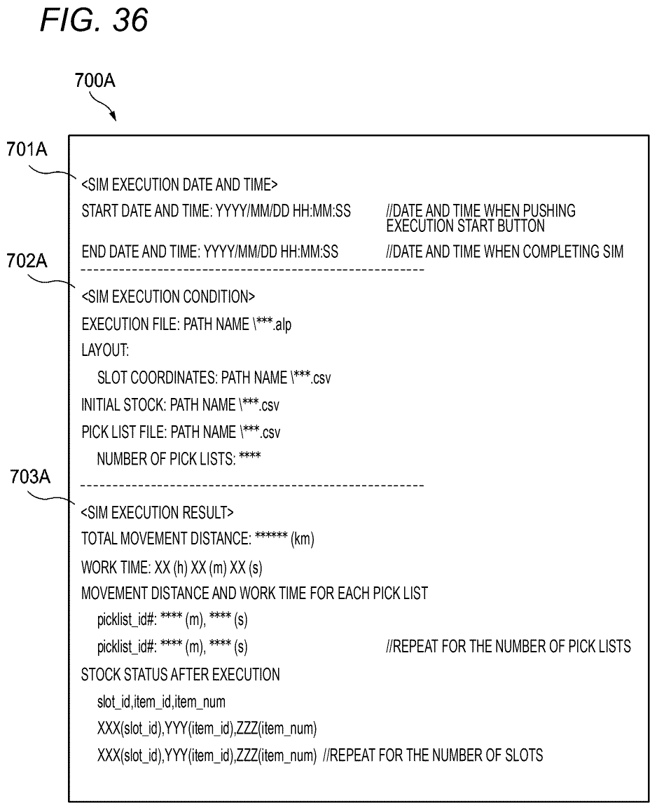

When the simulation is completed, the arithmetic device 2A outputs the simulation result (step St506A). Then, this processing flow ends. The output simulation results will be described later with reference to FIGS. 35 and 36.

### Example of Simulation Result

FIG. 35 is a schematic diagram illustrating an example of a simulation result according to Embodiment 2. A window 600A illustrated in FIG. 35 is displayed on, for example, the display (not illustrated). A simulation model is displayed in the window 600A. In the window 600A, a layout condition 601A, an execution condition 602A, an execution result 603A, and a simulation execution button 604A are displayed. Here, “SIM” means simulation. The window 600A illustrated in FIG. 35 is merely an example of the simulation result, and is not intended to limit an output content of the simulation result.

The layout condition 601A indicates a layout condition. In the example of FIG. 35, a slot is generated based on a CSV file “slot.csv”. Further, a path is generated based on a CSV file “aisle.csv”.

The execution condition 602A indicates execution conditions of the simulation. In the example of FIG. 35, the simulation is executed based on a CSV file “picklist.csv”. An initial stock quantity of the articles stored in each slot is set based on the CSV file “stock.csv”.

An execution result 603A indicates execution results of the simulation. Here, a pick distance indicates a distance by which the truck or the like moves in the simulation. The pick time indicates a time until a truck or the like completes transport and delivery in the simulation.

The user may execute the simulation by clicking the simulation execution button 604A with, for example a mouse (not illustrated). Alternatively, the simulation may be executed by operating a keyboard or the like (not illustrated).

FIG. 36 is a schematic diagram illustrating an example of the simulation result according to Embodiment 2. The arithmetic device 2A may output the simulation result as a text file 700A illustrated in FIG. 36.

In the example of FIG. 36, a simulation execution date and time 701A, a simulation execution condition 702A, and a simulation execution result 703A are described in the text file 700A. The text file 700A illustrated in FIG. 36 is merely an example of the simulation result, and is not intended to limit the output content of the simulation result.

The simulation execution date and time 701A describes a date and time when a button for executing the simulation, such as the simulation execution button 604A illustrated in FIG. 35, is pressed. Further, the simulation execution date and time 701A describes the date and time when the simulation is completed.

In the simulation execution condition 702A, a file for executing the simulation is described. The example of FIG. 36 illustrates that the simulation is executed by an ALP file “***.alp”. The type of a simulation execution file is not limited thereto. The simulation execution condition 702A describes the number of pick lists in addition to description corresponding to the layout condition 601A and the execution condition 602A illustrated in FIG. 35.

In the simulation execution result 703A, a distance by which the truck or the like moves in the simulation is described as a total movement distance. In addition, a time until the transport and delivery is completed in the simulation is described as a work time. Further, the movement distance and the work time for each pick list and the stock status for each slot after the execution of the simulation are described.

### Summary of Embodiment 2

The following techniques are disclosed by the above description of Embodiment 2.

### Technique B12

In the simulation model generation method according to Technique B1, the management system may manage the stock status of the articles stored in each of a plurality of bases, the arithmetic device may receive designation of a simulation target base by a user operation, and the arithmetic device may acquire slot information of the simulation target base from the management system according to the designation.

Accordingly, the arithmetic device can automatically generate a simulation model for simulating physical distribution between the designated simulation target bases. Accordingly, for example, it is possible to examine measures related to the physical distribution work.

### Technique B13

In the simulation model generation method according to Technique B12, the arithmetic device may generate conversion slot information by performing, on the slot information, data conversion processing for standardizing slot information that is used identically or differently for each management system or each base; and may generate the simulation model based on the conversion slot information.

Accordingly, the arithmetic device can share the slot information even when the slot information is different for each management system or each base.

### Technique B14

In the simulation model generation method according to Technique B13, the arithmetic device may generate path information of a path between simulation target bases based on the conversion slot information.

Accordingly, the arithmetic device can generate a path between the simulation target bases as a part of the model.

### Technique B15

In the simulation model generation method according to Technique B14, the arithmetic device may generate a layout of the simulation model based on the conversion slot information and the path information.

Accordingly, the arithmetic device can generate the layout of the model for the simulation of the physical distribution work.

### Technique B16

In the simulation model generation method according to any one of Techniques B1 to B15, the arithmetic device may generate a pick list that is an execution condition of the simulation using an identifier of the slot.

Accordingly, the arithmetic device can examine the optimization of the warehouse work or the physical distribution work by executing the simulation.

### Technique B17

In the simulation model generation method according to Technique B16, the arithmetic device may generate stock information of the article stored in the slot based on the pick list.

Accordingly, the arithmetic device can prevent, for example, occurrence of an error in the stock status.

The functions of the various embodiments described above can also be implemented by processing of supplying programs and applications for implementing the functions of the various embodiments described above to a system or device using a network, a storage medium, or the like, and having one or more processors in a computer of that system or device read and execute the programs.

Further, the functions of the various embodiments described above may be implemented by a circuit (for example, an application specific integrated circuit (hereinafter, referred to as an “ASIC”) or an FPGA) that implements one or more functions.

Although the various embodiments according to the present disclosure have been described above with reference to the drawings, it is needless to say that the present disclosure is not limited to such examples. It is apparent to those skilled in the art that various changes, corrections, substitutions, additions, deletions, and equivalents can be conceived within the scope of the claims, and it should be understood that such changes, corrections, substitutions, additions, deletions, and equivalents also fall within the technical scope of the present disclosure. In addition, components in the various embodiments described above may be combined freely in a range without departing from the spirit of the invention.

For example, the generation of the simulation model implemented in Embodiment 1 and the generation of the simulation implemented in Embodiment 2 may be combined. For example, a simulation of the transport and delivery between bases and a simulation of picking in a base may be executed together. For example, when the user selects a certain warehouse from the simulation model 30A displayed on the display (not illustrated), the 3D model 30 indicating the inside of the warehouse may be displayed. As described above, the simulation model may be generated so that the user can check both the transport and delivery between the bases and the picking work in the base.

The present application is based on a Japanese patent application filed on May 17, 2023 (Japanese Patent Application No. 2023-081894), and the contents thereof are incorporated herein by reference.

### INDUSTRIAL APPLICABILITY

The technique of the present disclosure is useful as a simulation model generation method, a simulation model generation program, and a simulation model generation system.

### REFERENCE SIGNS LIST

1, 1A: simulation model generation system
2, 2A: arithmetic device
3-1, 3-s: warehouse management system
4-1-1, 4-1-m, 4-s-1, 4-s-n: warehouse PC
5, 5A: CPU
6, 6A: memory
7, 7A: storage device
8, 8A: input and output unit
9, 9A: communication unit
10, 10A: external interface unit
30: 3D model
31: shelf
32: passage
33: standby region
34: loading region
35: warehouse region
36-1, 36-2, 36-3, 36-4: wall
37: worker
600, 600A: window
700, 700A: text file
917: rectangular parallelepiped
3A-1, 3A-s: transport management system
4A-1-1, 4A-1-m, 4A-s-1, 4A-s-n: base PC
30A: simulation model
31A, 32A, 34A, 35A: base
33A: path

1. A simulation model generation method executed by an arithmetic device, the arithmetic device being connected to a management system that manages a stock state of articles so as to be able to perform data communication, the method comprising:
acquiring, from the management system, slot information including a position of a slot in which the articles are stored; and
generating a simulation model based on the slot information.

2. The simulation model generation method according to claim 1, wherein the management system
manages the stock status of the articles stored in each of a plurality of bases,
receives designation of a simulation target base by a user operation, and
acquires slot information of the simulation target base from the management system according to the designation.

3. The simulation model generation method according to claim 2, further comprising:
generating conversion slot information by performing, on the slot information, data conversion processing for standardizing slot information that is used identically or differently for each management system or each base; and
generating the simulation model based on the conversion slot information.

4. The simulation model generation method according to claim 3, further comprising:
generating path information of a path between the simulation target bases based on the conversion slot information.

5. The simulation model generation method according to claim 4, further comprising:
generating a layout of the simulation model based on the conversion slot information and the path information.

6. The simulation model generation method according to claim 1, wherein the management system
manages the stock state of the articles stored in each of a plurality of warehouses,
receives designation of a simulation target warehouse by a user operation, and
acquires, from the management system, slot information for storing articles stored in the simulation target warehouse according to the designation.

7. The simulation model generation method according to claim 6, further comprising:
generating conversion slot information by performing, on the slot information, data conversion processing for standardizing slot information that is used identically or differently for each management system or each warehouse; and
generating the simulation model based on the conversion slot information.

8. The simulation model generation method according to claim 7, further comprising:
determining, based on the simulation target warehouse designated by the user operation, whether the data conversion processing is necessary for slot information of the simulation target warehouse;
generating, in response to determining that the data conversion processing is necessary, the conversion slot information by performing the data conversion processing on the slot information; and
generating the simulation model based on the conversion slot information.

9. The simulation model generation method according to claim 8, wherein
passage information of a passage present in the simulation target warehouse is generated based on the conversion slot information.

10. The simulation model generation method according to claim 9, further comprising:
generating region information of at least one predetermined region present in the simulation target warehouse based on the conversion slot information and the passage information.

11. The simulation model generation method according to claim 10, wherein
wall information of a wall present in the simulation target warehouse is generated based on the region information.

12. The simulation model generation method according to claim 11, further comprising:
generating a 3D model of the simulation target warehouse based on the conversion slot information, the region information, and the wall information.

13. The simulation model generation method according to claim 12, wherein
the conversion slot information includes data of a position and a size of the slot in a cyber space,
the region information includes data of a position of the predetermined region in the cyber space,
the wall information includes data of a position and a height of the wall in the cyber space, and
the 3D model is generated by generating one or more rectangular parallelepipeds corresponding to each of the slot, the predetermined region, and the wall in the cyber space based on the data.

14. The simulation model generation method according to claim 1, wherein
a pick list that is an execution condition of the simulation is generated using an identifier of the slot.

15. The simulation model generation method according to claim 14, further comprising:
generating stock information of the articles stored in the slot based on the pick list.

16. A computer-readable storage medium that stores a program causing an arithmetic device, the arithmetic device being connected to a management system that manages stock information of articles so as to be able to perform data communication, to execute processing of:
acquiring, from the management system, slot information including a position of a slot in which the articles are stored; and
generating a simulation model based on the slot information.

17. A simulation model generation system including an arithmetic device, the arithmetic device being connected to a management system that manages a stock state of articles so as to be able to perform data communication, the simulation model generation system comprising:
by the arithmetic device,
acquiring slot information including a position of a slot in which the articles are stored from the management system; and
generating a simulation model based on the slot information.
